(19) United States
(12) Patent Application Publication
(10) Pub. No.: US 2012/0285515 A1
(43) Pub. Date: Nov. 15, 2012

(54) STRUCTURE INSTALLATION MOUNT, SUPPORT DEVICE FOR STRUCTURE INSTALLATION, AND SOLAR PHOTOVOLTAIC SYSTEM

(76) Inventor: Kenichi Sagayama, Osaka-shi (JP)

(21) Appl. No.: 13/519,014

(22) PCT Filed: Dec. 27, 2010
(86) PCT No.: PCT/JP2010/073611

§ 371 Date: Jun. 25, 2012

(30) Foreign Application Priority Data
Dec. 25, 2009 (JP) 2009-295136

(51) Int. Cl. H01L 23/12; F16M 13/02; H01L 31/048

(52) U.S. Cl. 136/251; 248/224.8

(57) ABSTRACT

The structure installation mount of the present invention is including cross-pieces 11 used for mounting a structure and fastening devices 15 used for securing the cross-pieces 11 to a foundation. The fastening device 15 has a supporting plate 15c having formed therein at least two through holes 15f spaced apart lengthwise of the cross-piece 11 when mounted to the cross-piece 11, and a base plate 15a having formed therein an elongated aperture 15e whose long dimension is equal to or longer than the distance measured in the most remote through holes between the perimeter edges of the through holes that are at their greatest distance apart lengthwise of the cross-piece 11. When the respective through holes overlapping with the through holes 15f formed in supporting plate 15c are viewed as a single group, the cross-piece 11 has multiple groups of through holes 11h formed in the longitudinal direction of the cross-piece 11. The supporting plate 15c and the cross-piece 11 are joined via mutually overlapping through holes 15f in the supporting plate 15c and the through holes 11h in cross-piece 11. The base plate 15a is joined to a foundation through the elongated aperture 15e of the fastening device 15.

### DESCRIPTION

1. Technical Field

The present invention relates to a structure installation mount for installing structures on the ground and flat roofs, a support device for structure installation, and a solar photovoltaic system that employs the mount.

2. Background Art

Conventional mounts of this type include mounts obtained by installing multiple cross-pieces and then mounting structures onto these cross-pieces in a bridging manner. In this type of configuration, it is necessary to adjust and set the position and spacing between the cross-pieces, and technologies have been proposed to facilitate the adjustment of the position of the cross-pieces.

For example, Patent Document 1 has disclosed a technology that allows for the position of the vertical bars (cross-pieces) to be adjusted by forming elongated apertures in the top surfaces of the bars and passing bolts protruding from a roof through the elongated apertures in the top surfaces of the bars, thereby enabling the bars to be moved through a distance equal the length of the elongated apertures in the bars.

In addition, Patent Document 2 discloses a technology that allows for the position of the cross-pieces to be adjusted by forming respective grooves on two sides of the cross-pieces and inserting the tips of bolts into these grooves, thereby enabling the cross-pieces to be moved along the grooves located on both sides of the cross-pieces.

### CITATION LIST

### Patent Document

Patent Document 1: JP 2003-239482A

Patent Document 2: JP H11-324259A

### DISCLOSURE OF INVENTION

### Problem to be Solved by the Invention

However, in the technology described in Patent Document 1, the length of the elongated apertures is limited because the strength of the bars is reduced when the elongated apertures in the top surfaces of the bars become too long. As a result, the problem with the technology of Patent Document 1 was a limited range of bar position adjustment.

Further, in the technology of Patent Document 2, due to the fact that the grooves on two sides of the cross-pieces are of the same length as the cross-pieces, the range of cross-piece position adjustment was wide, but the cross-sectional shape of the cross-piece was complex. Accordingly, the problem with the technology of Patent Document 2 was its high cost. For example, although cross-pieces of complex cross-sectional shapes could be fabricated by extruding aluminum materials, the use of the aluminum materials entailed an increase in cost.

The present invention, which was made by taking the above-described prior-art problems into consideration, is aimed at providing a structure installation mount, a support device for structure installation, and a solar photovoltaic system which, while being of a simple shape, afford a wide range of cross-piece position adjustment and achieve a cost reduction.

### Means for Solving Problem

In order to overcome the above-noted problems, the structure installation mount of the present invention includes cross-pieces for mounting a structure and fastening devices that are used to secure these cross-pieces to a foundation; the fastening devices have a supporting section having formed therein at least two through holes which, upon mounting to a cross-piece, are spaced apart lengthwise of the cross-piece, and a base section having formed therein an elongated aperture, whose long dimension is equal to or longer than a distance measured in the through holes that are farthest away from each other between perimeter edges of the through holes that are at their greatest distance apart lengthwise of the cross-piece; and, when the through holes formed in the supporting sections of the fastening devices and the respective through holes overlapping with these through holes are viewed as a single group, multiple groups of through holes are formed in the cross-pieces in a longitudinal direction of the cross-pieces; the supporting section of the fastening devices and the cross-pieces are joined via mutually overlapping through holes in the supporting sections of the fastening devices and the through holes in the cross-pieces; and the base sections of the fastening devices are joined to the foundation through the elongated apertures in the fastening devices.

Since in this type of structure installation mount the supporting sections of the fastening devices can be joined to the cross-pieces in locations where through holes in the supporting sections of the fastening devices overlap with a group of through holes in the cross-pieces and there are multiple groups of through holes formed in the cross-pieces, the positions, in which the fastening devices are joined to the cross-pieces, can be adjusted by shifting them in a spaced manner in accordance with the position of each group of through holes. In addition, since an elongated aperture whose long dimension is equal to or longer than the distance measured in a group of through holes between the perimeter edges of the through holes that are at their greatest distance apart is formed in the base section of the fastening device and the base section of the fastening device is joined to the foundation through the elongated apertures of the fastening device, the base section of the fastening device can be moved throughout the length of the elongated aperture, i.e. at least throughout the spacing distance of a group of through holes, and the mounting position of the fastening device can be adjusted in a continuous manner within this distance range. Consequently, if an arbitrary location on the foundation is used for reference, then the position of a fastening device can be adjusted in a continuous manner throughout the spacing distance of a group of through holes and, at the same time, if the position of a fastening device is used for reference, then the position of a cross-piece can be adjusted by shifting it in a spaced manner and the position of a cross-piece relative to an arbitrary location on the foundation can be freely adjusted and set throughout a wide range by adjusting both of them together.

Furthermore, there is no need for constructions involving cross-pieces and fastening devices of a complicated shape, which enables the use of inexpensive materials of superior strength, such as steel and the like.

In addition, in the structure installation mount of the present invention, the cross-pieces preferably have an upright plate that is set upright on the foundation and multiple groups of through holes are formed in the upright plate in the longitudinal direction of the cross-pieces.

This type of upright plate has superior ability to withstand loads applied by structures mounted onto the upright plates.

Furthermore, in the structure installation mount of the present invention, the cross-pieces are preferably formed by interconnecting multiple cross-piece members, and through holes overlapping with respective through holes in the supporting sections of the fastening devices are formed in two adjacent cross-piece members at a point of their interconnection such that the through holes sandwich the point of interconnection.

In this case, the supporting section of a fastening device can be joined to the point of interconnection between the two cross-piece members.

In addition, the structure installation mount of the present invention may also use a configuration, in which there are provided interconnecting devices having formed therein through holes respectively overlapping with the through holes in the supporting sections of the fastening devices; the two cross-piece members are joined to the interconnecting devices via mutually overlapping through holes in the cross-piece members and through holes in the interconnecting devices; and the two cross-piece members are interconnected via the interconnecting devices.

The interconnecting devices can be used to form elongated cross-pieces by interconnecting multiple cross-piece members.

Furthermore, the structure installation mount of the present invention may also use a configuration, in which the point of interconnection between two cross-piece members is sandwiched between the supporting section of a fastening device and an interconnecting device; the two cross-piece members, the supporting section of the fastening device, and the interconnecting device are joined together via mutually overlapping through holes in the cross-piece members, through holes in the supporting section of the fastening device, and through holes in the interconnecting device; and the two cross-piece members are interconnected via the fastening device and the interconnecting device.

If two cross-piece members are interconnected in this manner while being sandwiched between a fastening device and an interconnecting device, the strength of interconnection between the cross-piece members is increased.

In addition, the structure installation mount of the present invention may also use a configuration, in which the cross-pieces have a bottom plate, an upright plate bent from one edge of this bottom plate, and a top plate produced by bending from the top edge of the upright plate; the two cross-pieces are disposed parallel to each other; the upright plates of the cross-pieces are secured to the foundation using the fastening devices; and a structure is mounted onto the top plates of the cross-pieces in a bridging manner.

This type of cross-pieces, albeit of a simple cross-sectional shape, have superior load-bearing capacity and suitability for mass production.

Furthermore, in the structure installation mount of the present invention, the heights of the cross-pieces secured to the foundation are preferably different, the top plates of the cross-pieces are in largely the same inclined plane, and the structure is mounted onto the top plates of the cross-piece members at an angle.

This type of configuration allows for structures to be supported at an angle.

In addition, in the structure installation mount of the present invention, there are provided beam members, which are secured between the respective cross-pieces in a bridging manner, and stoppers at one end of the beam members are at the tilted lower side of the structure placed on the top plates of the cross-pieces and are provided so as to receive one edge of the structure.

This prevents the structures from shifting and falling in the direction of the downward tilt.

Furthermore, in the structure installation mount of the present invention, the foundation may be formed from foundation cross-pieces extending in a direction perpendicular to the above-mentioned cross-pieces and the base sections of the fastening devices may be joined to the foundation cross-pieces via the elongated apertures in the base sections.

As noted above, if an arbitrary location on the foundation is used for reference, then the position of the fastening devices can be adjusted in a continuous manner throughout the spacing distance of a group of through holes and, at the same time, if the position of the fastening devices is used for reference, then the position of the cross-pieces can be adjusted by shifting it in a spaced manner and, therefore, the position of the cross-pieces relative to an arbitrary location on the foundation can be freely adjusted and set throughout a wide range. Accordingly, the position of the cross-pieces relative to these foundation cross-pieces can be freely adjusted and set throughout the length of the cross-pieces.

Now, the support device for structure installation of the present invention includes cross-pieces and fastening devices; the fastening devices have a supporting section having formed therein at least two through holes which, upon mounting to a cross-piece, are spaced apart lengthwise of the cross-piece, and a base section having formed therein an elongated aperture, whose long dimension is equal to, or longer than, a distance measured in the through holes that are farthest away from each other between perimeter edges of the through holes that are at their greatest distance apart lengthwise of the cross-piece; and, when the through holes formed in the supporting sections of the fastening devices and the respective through holes overlapping with these through holes are viewed as a single group, multiple groups of through holes are formed in the cross-pieces in a longitudinal direction of the cross-pieces.

In addition, the solar photovoltaic system of the present invention is obtained by mounting structures, i.e. solar cell modules, onto the above-described structure installation mount of the present invention.

The same action and effects as in the above-described structure installation mount of the present invention are obtained in the support device for structure installation and the solar photovoltaic system of the present invention.

### Effects of the Invention

Since in this invention the supporting sections of the fastening devices can be joined to cross-pieces in locations where through holes in the supporting sections of the fastening devices overlap with a group of through holes in the cross-pieces and there are multiple groups of through holes formed in the cross-pieces, the positions, in which the fastening devices are joined to the cross-pieces, can be adjusted by shifting them in a spaced manner in accordance with the position of each group of through holes. In addition, since an elongated aperture, whose long dimension is equal to or longer than the distance measured in a group of through holes between the perimeter edges of the through holes that are at their greatest distance apart lengthwise of the cross-piece is formed in the base section of the fastening devices and the base section of the fastening devices is joined to the foundation through the elongated apertures in the fastening devices, the base section of the fastening devices can be moved throughout the length of the elongated aperture, i.e. at least throughout the spacing distance of a group of through holes, and the mounting position of the fastening device can be adjusted in a continuous manner within this distance range. Consequently, if an arbitrary location on the foundation is used for reference, then the position of a fastening device can be adjusted in a continuous manner throughout the spacing distance of a group of through holes and, at the same time, if the position of a fastening device is used for reference, then the position of a cross-piece can be adjusted by shifting it in a spaced manner and the position of a cross-piece relative to an arbitrary location on the foundation can be freely adjusted and set throughout a wide range by adjusting both of them together.

In addition, there is no need to use constructions involving cross-pieces and fastening devices of a complicated shape, which enables the use of inexpensive materials of superior strength such as steel and the like.

### BRIEF DESCRIPTION OF DRAWINGS

FIG. 1 is a perspective view illustrating a solar photovoltaic system utilizing an embodiment of the structure installation mount of the present invention.

FIG. 2 is a perspective view illustrating the structure installation mount of the present embodiment.

FIG. 3 is a side view illustrating the structure installation mount of the present embodiment.

FIG. 4 is an enlarged perspective view illustrating the vertical cross-piece, fastening device, and horizontal cross-piece, etc. of FIG. 2.

FIG. 5(a), (b), (c) represent a plan view, a back view, and a side view illustrating a cross-piece member used to form the lower horizontal cross-piece of FIG. 2.

FIG. 6(a), (b), (c) represent a plan view, a back view, and a side view illustrating a cross-piece member used to form the higher horizontal cross-piece of FIG. 2.

FIG. 7 is a plan view illustrating the contour of a T-shaped hole formed in the upright plate of the horizontal cross-piece of FIG. 2.

FIG. 8 is a perspective view illustrating an interconnecting device used to interconnect the lower cross-piece members shown in FIG. 5.

FIG. 9 is a perspective view illustrating an interconnecting device used to interconnect the higher cross-piece members shown in FIG. 6.

FIG. 10(a) is a perspective view illustrating the fastening device shown in FIG. 2, (b) is its plan view, and (c) is its front elevation view.

FIG. 11(a) is a plan view illustrating the beam member shown in FIG. 2, (b) is its side view, and (c) is its front elevation view.

FIG. 12 is an enlarged cross-sectional view illustrating the local neighborhood of the lower horizontal cross-piece of FIG. 3.

FIG. 13 is an enlarged cross-sectional view illustrating the local neighborhood of the higher horizontal cross-piece of FIG. 3.

FIG. 14 is a perspective view illustrating cross-piece members interconnected using the interconnecting device of FIG. 8.

FIG. 15 is a perspective view illustrating cross-piece members interconnected using an interconnecting device and a fastening device.

FIG. 16 is an enlarged cross-sectional view illustrating the frame member of the solar cell module shown in FIG. 1.

FIG. 17 is a perspective view illustrating the end sections of mutually adjacent solar cell modules secured using a mounting fitting unit mounted to the horizontal cross-piece shown in FIG. 2, as seen obliquely from above and from the front.

FIG. 18 is a perspective view illustrating the state of FIG. 17 as seen obliquely from above and from behind.

FIG. 19 is a perspective view illustrating the state of FIG. 17 as seen obliquely from below and from behind.

FIG. 20 is a cross-sectional view illustrating the state of FIG. 17.

FIG. 21 is a perspective view illustrating the compression fitting shown in FIG. 17.

FIG. 22 is a perspective view illustrating the load-bearing fitting shown in FIG. 17.

FIG. 23 is a plan view illustrating the load-bearing fitting shown in FIG. 22 in a bent state.

FIG. 24 is a perspective view illustrating the load-bearing fitting shown in FIG. 22 in a bent state, as seen from the front.

FIG. 25 is a perspective view illustrating the load-bearing fitting shown in FIG. 22 in a bent state, as seen from the back.

FIG. 26 is a perspective view illustrating the end section of a solar cell module secured using a mounting fitting unit mounted to the cross-piece member shown in FIG. 2, as seen obliquely from above and from the front.

FIG. 27 is a perspective view illustrating the state of FIG. 26 as seen obliquely from above and from behind.

FIG. 28 is a cross-sectional view illustrating the state of FIG. 26.

FIG. 29 is a perspective view illustrating the compression fitting shown in FIG. 26.

FIG. 30 is a diagram illustrating the procedure used to build the solar photovoltaic system of FIG. 1.

FIG. 31 is a diagram illustrating the procedure subsequent to FIG. 30.

FIG. 32 is a diagram illustrating the procedure subsequent to FIG. 31.

FIG. 33(a), (b) are diagrams illustrating the procedure subsequent to FIG. 32.

FIG. 34 is a perspective view illustrating a variation of the solar photovoltaic system of FIG. 1.

FIG. 35 is a perspective view illustrating a variation of the structure installation mount of FIG. 2.

### DESCRIPTION OF THE INVENTION

Embodiments of the present invention are described in detail below with reference to drawings.

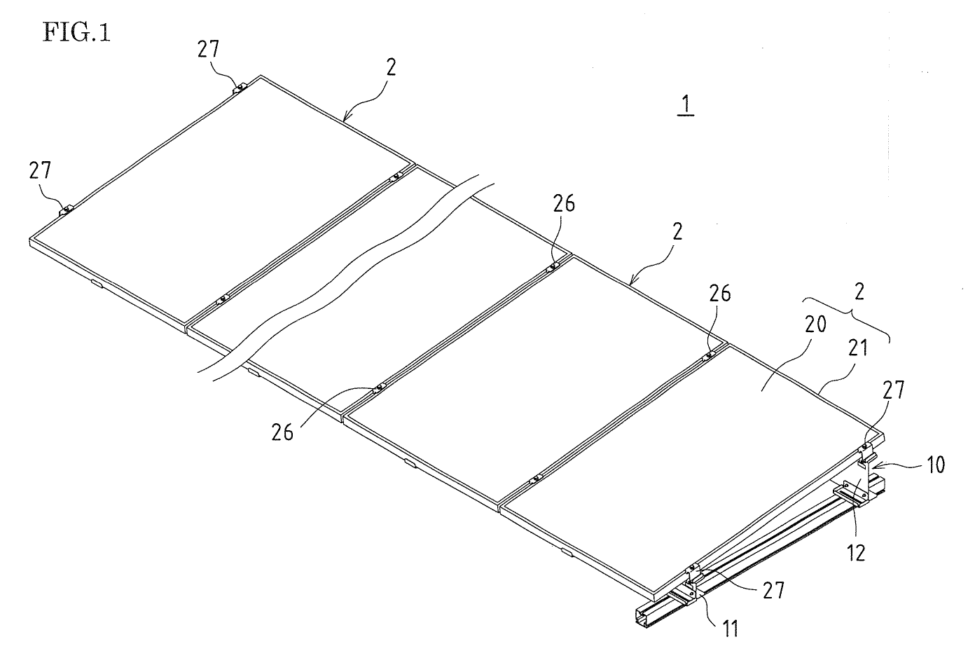

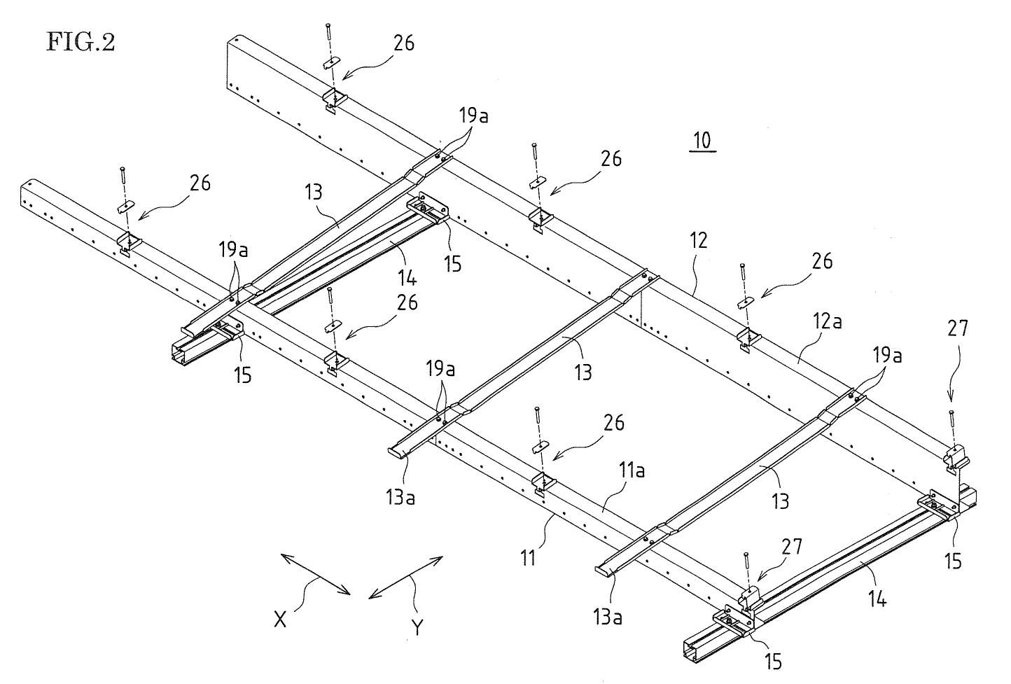

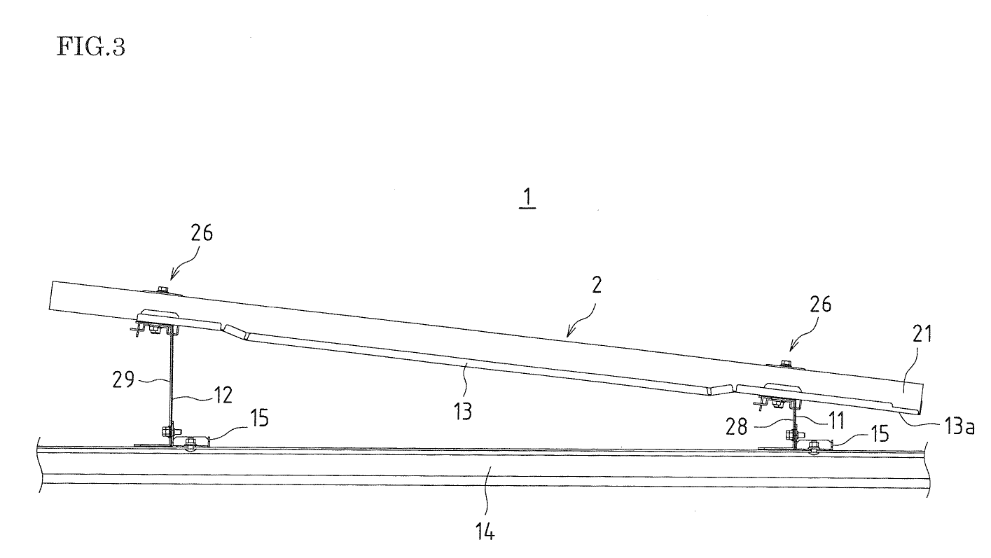

FIG. 1 is a perspective view illustrating a solar photovoltaic system utilizing an embodiment of the structure installation mount of the present invention. In addition, FIG. 2 is a perspective view illustrating the structure installation mount of the present embodiment. Further, FIG. 3 is a side view illustrating the structure installation mount of the present embodiment.

In the solar photovoltaic system 1 of FIG. 1, the structure installation mount 10 of the present embodiment is used to arrange and support multiple solar cell modules 2 in an inclined position. In the solar cell modules 2, the perimeter edges of the solar cell panels 20 are held by the frame members 21.

In the structure installation mount 10 of the present embodiment, as shown in FIG. 2 and FIG. 3, multiple vertical cross-pieces (foundation cross-pieces) 14 are disposed in a mutually parallel configuration and secured to a foundation surface, such as a flat roof, etc. Two horizontal cross-pieces 11, 12 are arranged at right angles to vertical cross-pieces 14 and these horizontal cross-pieces 11, 12 are placed on, and secured to, the vertical cross-pieces 14. Beam members 13 are positioned between the top plates 11a, 12a of the horizontal cross-pieces 11, 12 in a bridging manner. One end 13a of the beam members 13 is secured such that it intersects the top plate 11a of the horizontal cross-piece 11 and this end 13a of this beam member 13 extends beyond the horizontal cross-piece 11. The multiple solar cell modules 2 are placed on top of the respective beam members 13 and mounted between the horizontal cross-pieces 11, 12 in a bridging manner.

It should be noted that the longitudinal direction of the horizontal cross-pieces 11, 12 is designated as the X direction (horizontal direction) and the direction perpendicular to this X direction is designated as Y direction (vertical direction).

The vertical cross-pieces 14 are disposed parallel to each other, but their positions are not fixed. For example, although multiple anchor bolts used for securing vertical cross-pieces 14 can be provided on a flat roof during the construction of a building, it is impossible to specify or predict the installation location of each anchor bolt because the installation location of the anchor bolts will change in various ways for reasons such as the structure of the building, the strength of attachment of the anchor bolts, and the like. Therefore, the location of installation of the vertical cross-pieces 14 will be uncertain.

The horizontal cross-pieces 11, 12 are placed on, and secured to, the vertical cross-pieces 14. Since the location of installation of each solar cell module 2 is determined by the positions of the horizontal cross-pieces 11, 12, the positions of the horizontal cross-pieces 11, 12 have to be appropriately adjusted and set. However, since the location of installation of the vertical cross-pieces 14 is uncertain, the horizontal cross-pieces 11, 12 must be capable of being secured at arbitrary locations on the vertical cross-pieces 14 in order to appropriately adjust and set the positions of the horizontal cross-pieces 11, 12.

For this reason, a construction is implemented, in which the horizontal cross-pieces 11, 12 can be secured at arbitrary locations on the vertical cross-pieces 14 by combining the horizontal cross-pieces 11, 12 with fastening devices 15.

The horizontal cross-pieces 11, 12, which are of the same length as the length in the direction of arrangement of the solar cell modules 2 in the solar photovoltaic system 1 of FIG. 1, are imparted the appropriate length by interconnecting multiple short cross-piece members. Dedicated interconnecting devices, to be described hereinafter, or a set of fastening devices 15 are used to interconnect the cross-piece members.

The heights of the horizontal cross-pieces 11, 12 are different, with the horizontal cross-piece 11 being lower and the horizontal cross-piece 12 being higher. The solar cell modules 2 are inclined in the direction of incidence of solar light by mounting the solar cell modules 2 on such horizontal cross-pieces 11, 12 of different height. Consequently, the larger the elevation difference between the horizontal cross-pieces 11, 12, the larger the tilt angle of the solar cell modules 2.

Mounting fitting units 26 or 27, which are used to secure and support both sides of the frame members 21 of the solar cell modules 2, are mounted to the top plates 11a, 12a of the horizontal cross-pieces 11, 12. The mounting fitting units 26 are intended for simultaneously securing the frame members 21 of the two mutually adjacent solar cell modules 2 in the solar photovoltaic system 1. In addition, the mounting fitting units 27 are intended for securing the frame members 21 of the solar cell modules 2 positioned on the two outer edges of the solar photovoltaic system 1.

The vertical cross-pieces 14, horizontal cross-pieces 11, 12, fastening devices 15, and beam members 13, etc. will be described below on an individual basis.

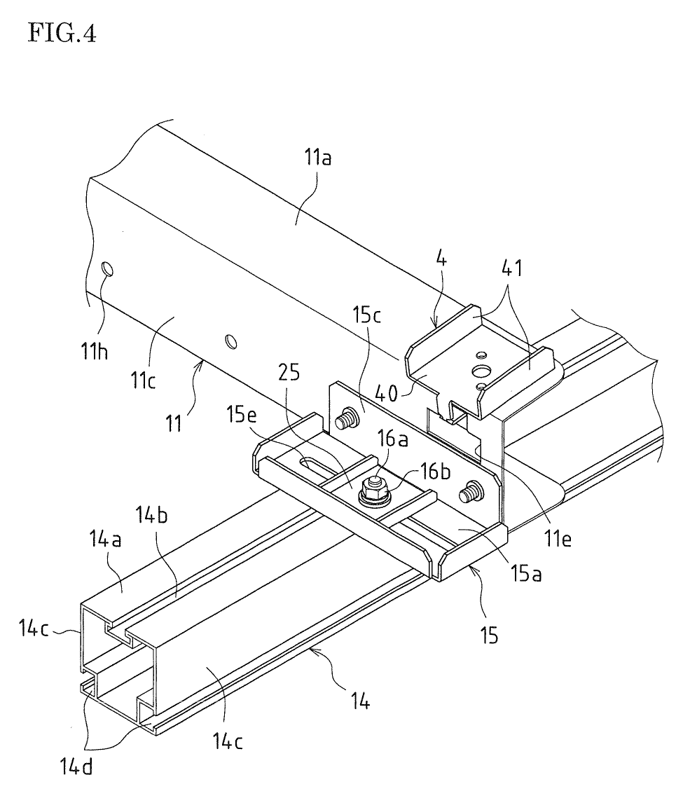

FIG. 4 is an enlarged perspective view illustrating a vertical cross-pieces 14, a fastening device 15, and a horizontal cross-piece 11. As shown in FIG. 4, the vertical cross-piece 14, which is a hollow element formed, for example, by subjecting an aluminum material to extrusion processing, has a mating groove 14b formed in the center of the top surface 14a and grooves 14d formed in both side faces 14c. The bottom of the mating groove 14b in the top surface 14a serves as a wide-width guide and the portion in the vicinity of the top surface 14a forms a narrow-width slit. The head of a bolt is supported for free movement in the wide width guide and the shank section of the bolt protrudes from the narrow-width slit. In addition, an engagement fitting (not shown) is engaged with the grooves 14d in both the side faces 14c. This engagement fitting is secured to the surface of a foundation such as a flat roof and the like with anchor bolts, thereby securing and supporting the vertical cross-piece 14 on the foundation surface.

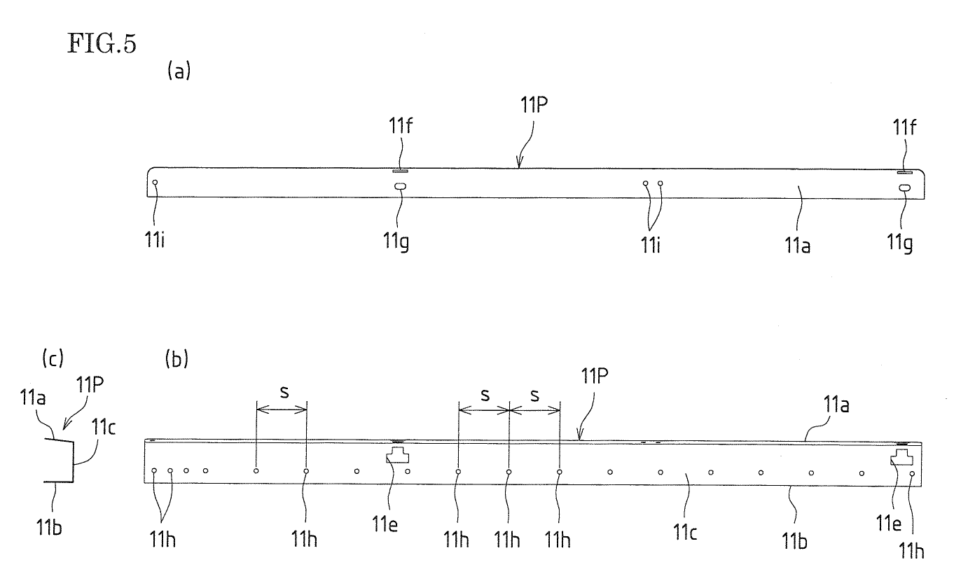

FIG. 5(a), (b), and (c) represent a plan view, a back view, and a side view illustrating a cross-piece member 11P used to form the horizontal cross-piece 11. As shown in FIG. 5(a)-(c), the cross-piece member 11P has an upright plate 11c and, in addition, a bottom plate 11b and a top plate 11a, which are formed by bending the bottom and top edges of the upright plate 11c in the same direction, thereby producing a substantially U-shaped cross-sectional shape. The bottom plate 11b is placed on the vertical cross-pieces 14 in a bridging manner and the upright plate 11c is set upright on the vertical cross-pieces 14. T-shaped holes 11e, positioning slits 11f, and oblong apertures 11g, which are used for mounting the mounting fitting units 26 or 27 in each mounting position of these mounting fitting units, are formed in the upright plate 11c and top plate 11a. In addition, multiple through holes 11h are formed in the upright plate 11c at a preset spacing s. It should be noted that the term “preset spacing s” refers to the fact that the distance between the centers of the through holes 11h is a constant value s. In addition, multiple through holes 11h are formed in the vicinity of an end section of the upright plate 11c, starting from the end section, with a spacing smaller than the preset spacing s.

In the case of the multiple cross-piece members 11P, the end sections of adjacent cross-piece members 11P are interconnected in mutually abutting relationship, thereby forming a single horizontal cross-piece 11. In the horizontal cross-piece 11, the respective through holes 11h formed in the vicinity of the end sections of adjacent cross-piece members 11P are spaced apart at a preset spacing s so as to sandwich the location of interconnection of the cross-piece members 11P. In other words, the positions of the through holes 11h are set such that the through holes 11h located in the vicinity of the end sections of the cross-piece members 11P are spaced apart at a preset spacing s when the end sections of the cross-piece members 11P are interconnected in mutually abutting relationship.

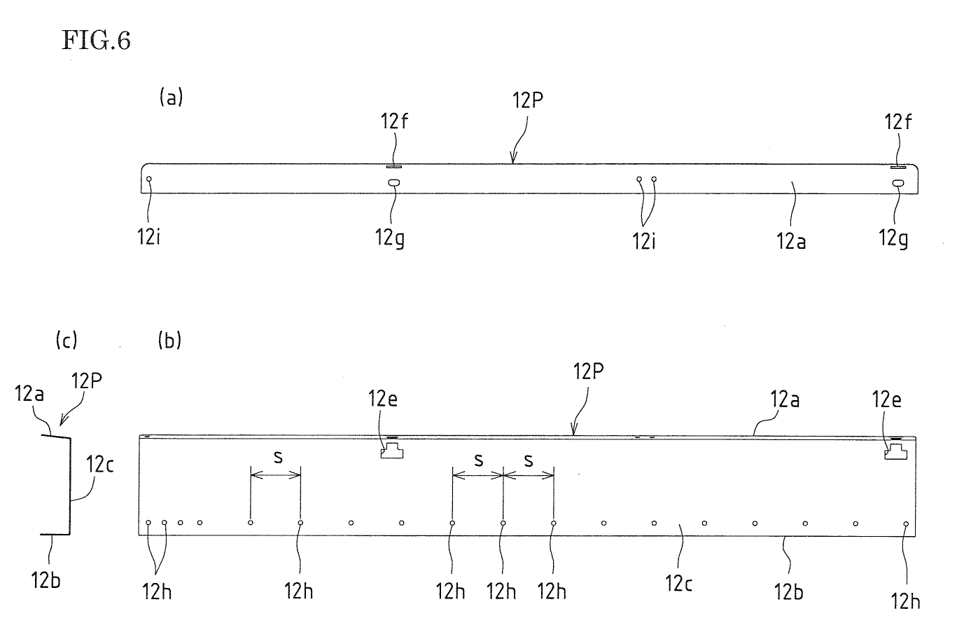

FIG. 6(a), (b), and (c) represent a plan view, a back view, and a side view illustrating a cross-piece member 12P used to form the horizontal cross-pieces 12. As shown in FIG. 6(a)-(c), in the same manner as the cross-piece member 11P, the cross-piece member 12P has an upright plate 12c and, in addition, a bottom plate 12b and a top plate 12a, which are formed by bending the bottom and top edges of the upright plate 12c in the same direction, thereby producing a substantially U-shaped cross-sectional shape. The bottom plate 12b is placed on the vertical cross-pieces 14 in a bridging manner and the upright plate 12c is set upright on the vertical cross-pieces 14. T-shaped holes 12e, positioning slits 12f, and oblong apertures 12g, which are used for mounting the mounting fitting units 26 or 27, are formed in the upright plate 12c and top plate 12a. In addition, multiple through holes 12h are formed in the upright plate 12c at a preset spacing s (identical to the preset spacing s between the through holes 11h in the upright plate 11c of the horizontal cross-pieces 11). Furthermore, multiple through holes 12h are formed in the vicinity of an end section of the upright plate 12c, away from the end section, with a spacing smaller than the preset spacing s.

In the same manner as in the cross-piece members 11P, in the multiple cross-piece members 12P, the end sections of adjacent cross-piece members 12P are interconnected in mutually abutting relationship, thereby forming a single horizontal cross-piece 12. In addition, the respective through holes 12h formed the vicinity of the end sections of the adjacent cross-piece members 12P are spaced apart at a preset spacing s such the through holes sandwich the point of interconnection of the cross-piece members 12P.

It should be noted that there are cross-piece members 11P, 12P of various lengths. The cross-piece member 11P, 12P of these various lengths are combined and interconnected as appropriate to provide the required total length of the horizontal cross-pieces 11, 12.

As can be seen from FIG. 5(c) and FIG. 6(c), the upright plates 11c, 12c of the horizontal cross-pieces 11, 12 (cross-piece members 11P, 12P) are set vertically with respect to the respective bottom plates 11b and 12b. Therefore, when the bottom plates lib, 12b are placed on the vertical cross-pieces 14, the upright plates 11c, 12c stands vertically with respect to the top surface of the vertical cross-pieces 14 (top surface of the foundation). For this reason, the horizontal cross-pieces 11, 12 have a superior ability to bear loads applied vertically from above and can firmly support loads applied to the respective top plates 11a, 12a.

The top plates 11a, 12a of the horizontal cross-pieces 11, 12 are bent so as make the same acute angle with a plane normal to the respective upright plates 11c, 12c. In addition, the horizontal cross-piece 11 is lower and the horizontal cross-piece 12 is higher. For this reason, when the bottom plates lib, 12b of the horizontal cross-pieces 11, 12 are placed on the foundation surface and the horizontal cross-pieces 11, 12 are disposed in parallel to each other at predetermined spacing, the respective top plates 11a,12a are positioned in substantially the same inclined plane and the solar cell modules 2 placed on these top plates 11a, 12a are disposed and tilted along this inclined plane.

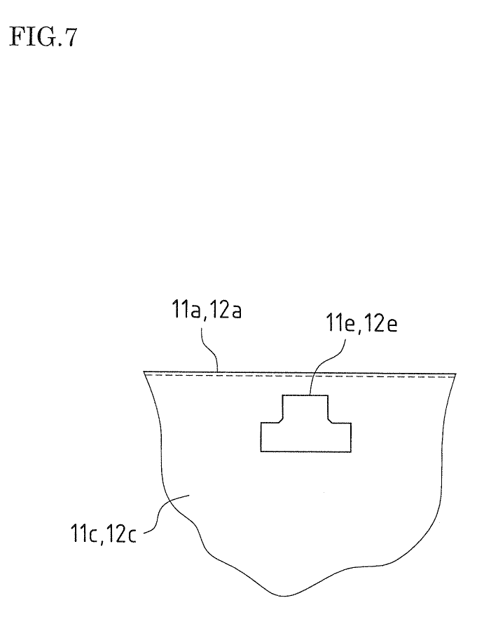

As shown in FIG. 7, the T-shaped holes 11e, 12e in the upright plates 11c, 12c of the horizontal cross-pieces 11, 12 (cross-piece members 11P, 12P) are formed away from the flexure sections (corners) between the upright plates 11c, 12c and top plates 11a, 12a. For this reason, there is no decrease due to the T-shaped holes 11e, 12e in the strength of the flexure sections between the upright plates 11c, 12c and top plates 11a, 12a and the strength of the horizontal cross-pieces 11, 12 can be maintained.

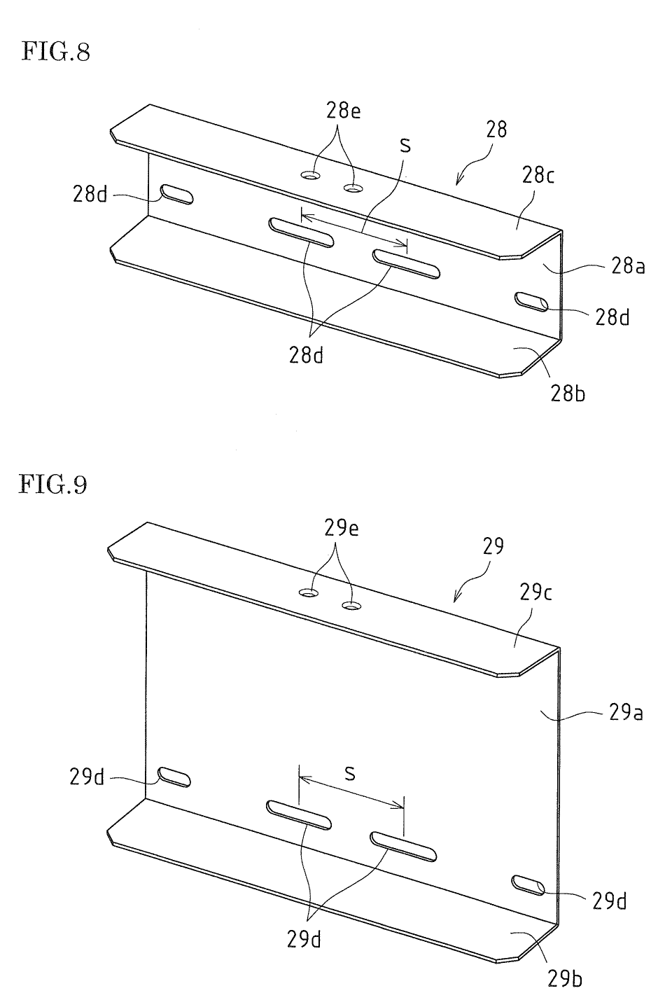

FIG. 8 is a perspective view illustrating an interconnecting device used to interconnect multiple cross-piece members 11P. As shown in FIG. 8, the interconnecting device 28 has an upright plate 28a and, in addition, a bottom plate 28b and a top plate 28c, which are formed by bending the bottom and top edges of the upright plate 28a, thereby producing a substantially U-shaped cross-sectional shape. Multiple oblong apertures 28d etc. are formed in the upright plate 28a and these oblong apertures 28d are positioned so as to overlap with the through holes 11h in the upright plate 11c of the cross-piece member 11P. In addition, a pair of through holes 28e are formed in the top plate 28c. The interconnecting device 28 fits inside the U-shaped cross-sectional shape of the cross-piece member 11P. The upright plate 28a, bottom plate 28b, and top plate 28c overlap with the upright plate 11c, bottom plate 11b, and top plate 11a of the cross-piece member 11P.

FIG. 9 is a perspective view illustrating an interconnecting device used to interconnect multiple cross-piece members 12P. As shown in FIG. 9, the interconnecting device 29 has an upright plate 29a and, in addition, a bottom plate 29b and a top plate 29c, which are formed by bending the bottom and top edges of the upright plate 29a, thereby producing a substantially U-shaped cross-sectional shape. Multiple oblong apertures 29d etc. are formed in the upright plate 29a and these oblong apertures 29d are positioned so as to overlap with the through holes 12h in the upright plate 12c of the cross-piece member 12P. In addition, a pair of through holes 29e are formed in the top plate 29c. The interconnecting device 29 fits inside the U-shaped cross-sectional shape of the cross-piece member 12P. The upright plate 29a, bottom plate 29b, and top plate 29c overlap with the upright plate 12c, bottom plate 12b, and top plate 12a of the cross-piece member 12P.

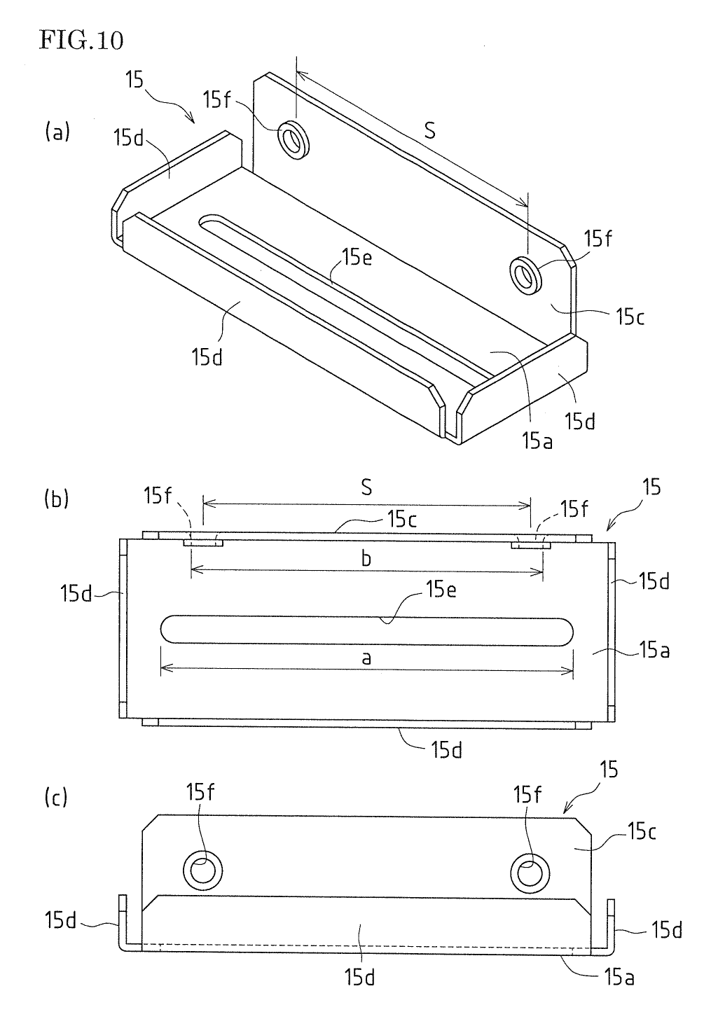

FIG. 10(a), (b), (c) represent a perspective view, a plan view, and a front view illustrating a fastening device 15 used for fastening the horizontal cross-pieces 11, 12 to the vertical cross-pieces 14. As shown in FIG. 10, the fastening device 15 has a base plate (base section) 15a and a supporting plate (supporting section) 15c formed by bending one edge of the base plate 15a upward. Ribs 15d, which are provided at the other three edges of the base plate 15a, are formed by bending these three edges upward. The base plate 15a is reinforced by these ribs 15d. In addition, two screw holes 15f are formed in the supporting plate 15c of the fastening device 15. The gap between these screw holes 15f matches the preset spacing s between the through holes 11h, 12h in the upright plates 11c, 12c of the horizontal cross-pieces 11, 12. The distance from the bottom surface of the base plate 15a to the screw holes 15f is the same as the distance from the bottom surface of the bottom plates lib, 12b of the horizontal cross-pieces 11, 12 to the through holes 11h, 12h.

Furthermore, an elongated aperture 15e is formed in the base plate 15a. The length a of this elongated aperture 15e is set to be equal to, or greater than, the distance b between the perimeter edge portions of the screw holes 15f (distance b=preset spacing s+(diameter of screw hole 15f)) that are at their greatest distance apart in the two screw holes 15f in the supporting plate 15c (a≧b).

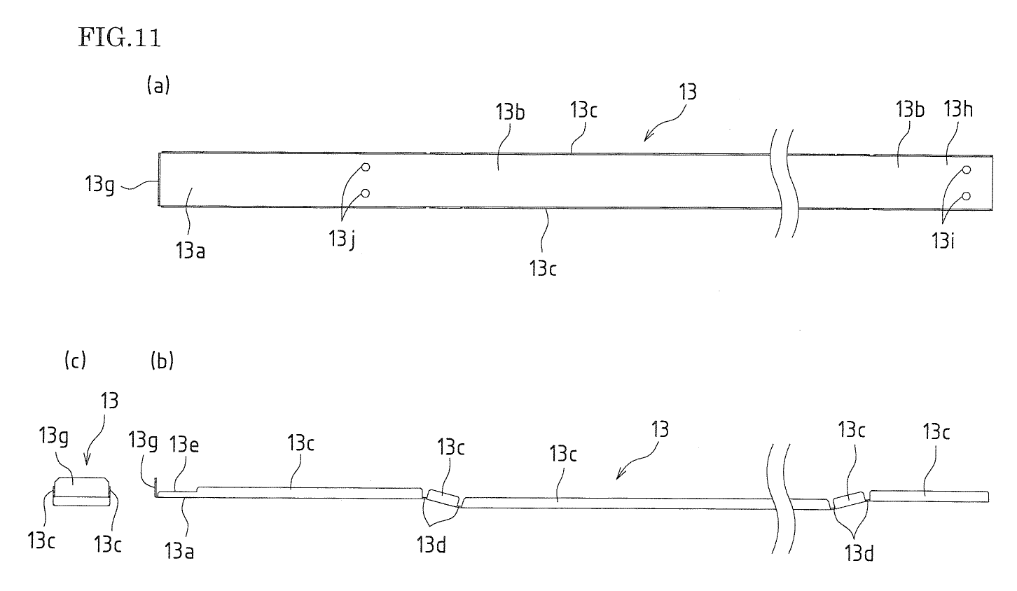

FIG. 11(a), (b), (c) represent a plan view, a side view, and a front view illustrating a beam member 13. As shown in FIG. 11, the beam member 13 has a substantially U-shaped cross-sectional shape comprising a main plate 13b and side plates 13c on both sides of the main plate 13b. The side plates 13c of the beam member 13 have cutouts 13d is formed at 4 locations such that the main plate 13b can be bent at these locations.

In addition, a cutout 13e is formed in each side plate 13c in the vicinity of an end 13a of the beam member 13, with an upwardly bent stopper 13g provided at this end 13a.

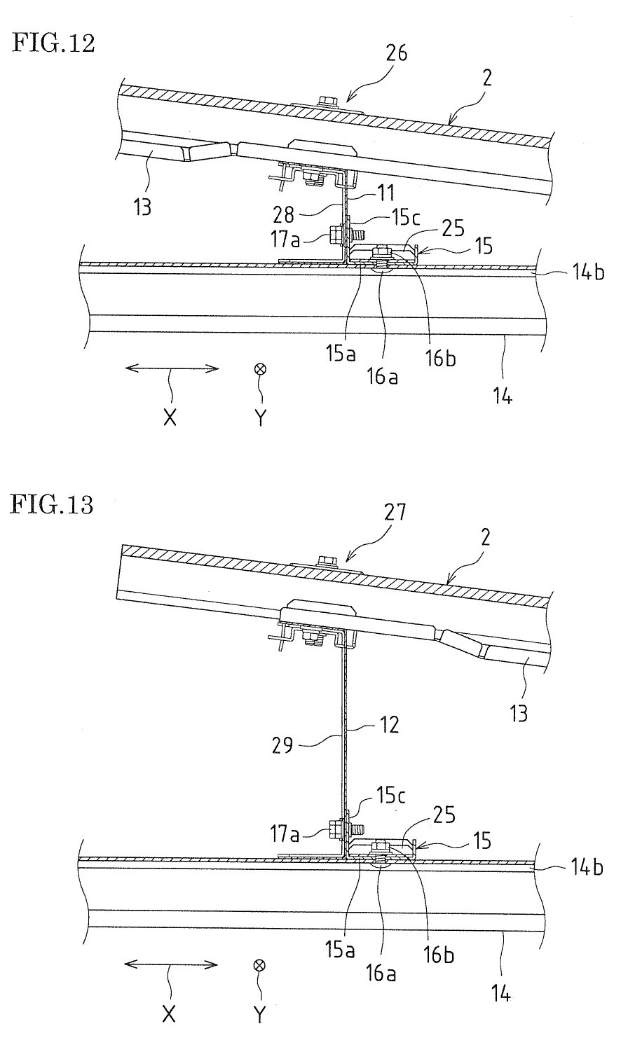

The construction of the structure installation mount of the present embodiment will be described in detail below. FIG. 12 is an enlarged cross-sectional view illustrating the local neighborhood of the horizontal cross-piece 11 used in the structure installation mount of the present embodiment. In addition, FIG. 13 is an enlarged cross-sectional view illustrating the local neighborhood of the horizontal cross-piece 12 used in the structure installation mount of the present embodiment.

In FIG. 3, FIG. 12, and FIG. 13, the vertical cross-piece 14 is secured to a foundation surface such as a flat roof and the like using an engagement fitting and an anchor bolt (not shown). When the head of the bolt 16a is inserted into the wide-width guide of the mating groove 14b of this vertical cross-piece 14 and the shank section of the bolt 16a protrudes from the narrow width slit of the mating groove 14b, the position of the bolt 16a is adjusted as appropriate by moving it along the mating groove 14b of the vertical cross-piece 14.

Because two fastening devices 15 are required to secure the horizontal cross-pieces 11, 12 to the vertical cross-pieces 14, the position of the two bolts 16a is adjusted by moving them in the X direction along the mating grooves 14b of the vertical cross-pieces 14 such that these bolts 16a are disposed at a distance corresponding to the gap between the horizontal cross-pieces 11, 12.

In addition, as shown in FIG. 12, the horizontal cross-piece 11 is placed on the vertical cross-pieces 14 facing in a direction (X direction), in which the horizontal cross-piece 11 is at right angles to the vertical cross-pieces 14, and the horizontal cross-piece 11 is precisely positioned by moving it both in the X direction and in the Y direction. After this, the respective shank sections of the bolts 16a are passed through the elongated apertures 15e in the base plates 15a of the two fastening devices 15 and the base plates 15a of the fastening devices 15 are placed on the upper surfaces 14a of the vertical cross-pieces 14 and, in each fastening device 15, the supporting plate 15c of the fastening device 15 is brought into abutment with the upright plate 11c of the horizontal cross-piece 11, the two screw holes 15f of the supporting plates 15c of the fastening device 15 are made to overlap with the two through holes 11h of the upright plate 11c of the horizontal cross-piece 11 by moving the supporting plate 15c of the fastening device 15 in the X direction on the vertical cross-pieces 14, the bolts 17a are threadedly engaged with the screw holes 15f of the fastening device 15 via the through holes 11h of the horizontal cross-piece 11, and the supporting plate 15c of the fastening device 15 is secured to the upright plate 11c of the horizontal cross-piece 11 (see FIG. 4). Furthermore, the shank section of the bolt 16a is passed through a hole in the reinforcement fitting 25, which has a U-shaped cross-sectional shape, the reinforcement fitting 25 is superimposed on the base plate 15a of the fastening device 15, and a nut 16b is threadedly engaged with, and tightened on, the shank section of the bolt 16a, thereby joining the fastening device 15 to the vertical cross-piece 14. As a result, the horizontal cross-piece 11 is secured to the vertical cross-pieces 14.

In a similar manner, as shown in FIG. 13, the horizontal cross-piece 12 is placed on the vertical cross-pieces 14 facing in a direction (X direction), in which the horizontal cross-piece 12 is at right angles with the vertical cross-pieces 14, and the horizontal cross-piece 12 is positioned by moving it either in the X direction or in the Y direction. Subsequently, the respective shank sections of the bolts 16a are passed through the elongated apertures 15e in the base plates 15a of the two fastening devices 15 and the base plates 15a of the fastening devices 15 are placed on the upper surfaces 14a of the vertical cross-pieces 14 and, in each fastening device 15, the two screw holes 15f of the supporting plates 15c of the fastening device 15 are made to overlap with the two through holes 12h of the upright plate 12c of the horizontal cross-piece 12 by moving the supporting plate 15c of the fastening device 15 in the X direction on the vertical cross-pieces 14, the bolts 17a are threadedly engaged with the screw holes 15f of the fastening device 15 via the through holes 12h of the horizontal cross-piece 12, and the supporting plate 15c of the fastening device 15 is secured to the upright plate 12c of the horizontal cross-piece 12. Furthermore, the reinforcement fitting 25 is superimposed on the base plate 15a of the fastening device 15 and a nut 16b is threadedly engaged with, and tightened on, the shank section of the bolt 16a, thereby joining the fastening device 15 to the vertical cross-piece 14. As a result, the horizontal cross-piece 12 is secured to the vertical cross-pieces 14.

The manner, in which the position of the horizontal cross-piece 11 and fastening device 15 is adjusted in the X direction, is explained below. Due to the fact that multiple through holes 11h are formed at a preset spacing s in the upright plate 11c of the horizontal cross-piece 11 and two screw holes 15f are formed at a preset spacing s in the supporting plate 15c of the fastening device 15, when the screw holes 15f of the supporting plate 15c of the fastening device 15 are made to overlap with to the two through holes 11h of the upright plate 11c of the horizontal cross-piece 11, the supporting plate 15c of the fastening device 15 can be joined to the upright plate 11c of the horizontal cross-piece 11 at location where they overlap and the location where the fastening devices 15 are joined to the horizontal cross-piece 11 can be adjusted at a preset spacing s.

In addition, since a long elongated aperture 15e with a length of a (a≧b (distance b=preset spacing s+(diameter of the screw holes 15f)) is formed in the base plate 15a of the fastening device 15 and the base plate 15a of the fastening device 15 is joined to the vertical cross-piece 14 via the elongated aperture 15e in the base plate 15a of the fastening device 15, the base plate 15a of the fastening device 15 can be moved at least through a distance equal to the preset spacing s and the mounting position of the fastening device 15 can be adjusted in a continuous manner within this distance range.

Accordingly, if the position of the cross-pieces 14 is used for reference, then the position of the fastening device 15 can be adjusted in a continuous manner at least throughout a distance range equal to the preset spacing s, and at the same time, if the position of the fastening device 15 is used for reference, then the position of the horizontal cross-piece 11 can be adjusted at a preset spacing s, and the position of the horizontal cross-piece 11 relative to the vertical cross-pieces 14 can be freely adjusted and set throughout the length of the horizontal cross-piece 11 by adjusting both of them together.

In order to facilitate the adjustment of the position of the horizontal cross-piece 11 relative to the vertical cross-pieces 14, it is preferable to make the length a of the elongated aperture 15e in the base plate 15a of the fastening device 15 adequately longer than the distance b (a>b). As a result, the range of continuous position adjustment of the fastening device 15c relative to the vertical cross-pieces 14 is expanded and the range of continuous position adjustment of the horizontal cross-piece 11 relative to the vertical cross-pieces 14 is expanded as well.

As noted above, while the position of the vertical cross-pieces 14 on the flat roof is uncertain, the position of the horizontal cross-piece 11 relative to the vertical cross-pieces 14 can be freely adjusted in this manner, and, therefore, the horizontal cross-piece 11 can be secured in any given position on the vertical cross-pieces 14.

The horizontal cross-piece 11 is produced by interconnecting multiple cross-piece members 11P and the fastening devices 15 are therefore used separately for each cross-piece member 11P to secure the cross-piece member 11P to the vertical cross-pieces 14. However, due to the fact that multiple through holes 11h are formed in the respective cross-piece members 11P at a preset spacing s, for any of the cross-piece members 11P, the position of the cross-piece member 11P relative to the vertical cross-pieces 14 can be freely adjusted and set throughout the length of the cross-piece member 11P, and a single horizontal cross-piece 11 can be formed by bringing the cross-piece members 11P in abutment with each other on the vertical cross-pieces 14.

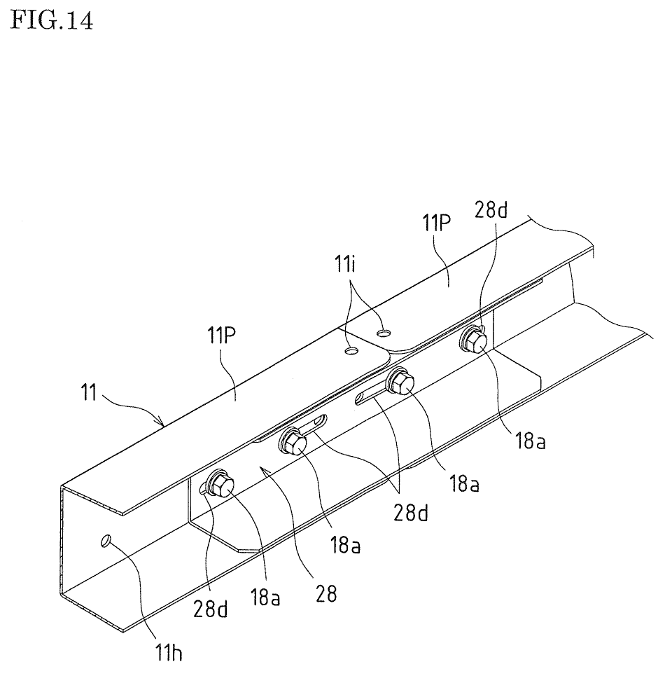

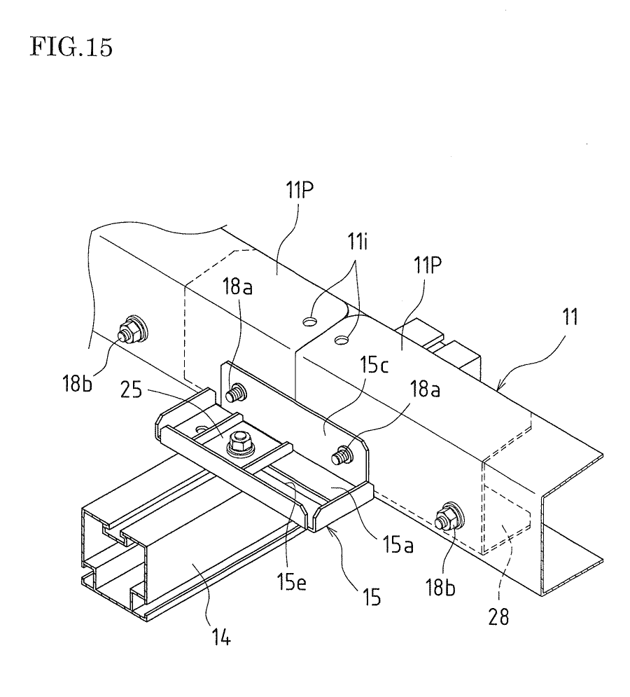

As shown in FIG. 14, an interconnecting device 28 fits inside the U-shaped cross-sectional shape of the cross-piece members 11P at the point of interconnection between the cross-piece members 11P such that the oblong apertures 28d of the interconnecting device 28 overlap with the respective through holes 11h spaced apart at a preset spacing s so as to sandwich the point of interconnection between the cross-piece members 11P, multiple bolts 18a are passed through the oblong apertures 28d and through holes 11h, and respective nuts 18b (shown in FIG. 15) are threadedly engaged with, and tightened on, these bolts 18a.

In addition, as shown in FIG. 15, the point of interconnection between the cross-piece members 11P may be secured to the vertical cross-piece 14. In such a case, an interconnecting device 28 and a fastening device 15 are both disposed at this point of interconnection and the upright plates 11c of the cross-piece members 11P are sandwiched between the upright plate 28a of the interconnecting device 28 and the supporting plate 15c of the fastening device 15 such that the oblong apertures 28d of the interconnecting device 28, through holes 11h of the cross-piece members 11P, and screw holes 15f of the fastening device 15 are mutually superposed. The two bolts 18a are threadedly engaged with the screw holes 15f via the oblong apertures 28d and through holes 11h and tightened. In addition, another two bolts 18a are passed through the oblong apertures 28d and through holes 11h, threadedly engaged with the nuts 18b, and tightened. When the cross-piece members 11P are interconnected using an interconnecting device 28 in conjunction with a fastening device 15, the strength of interconnection is improved.

Similarly, since in the case of the horizontal cross-piece 12 there are multiple through holes 12h formed at a preset spacing s in the upright plate 12c and two screw holes 15f are formed at a preset spacing s in the supporting plate 15c of the fastening device 15, the location where the fastening device 15 is joined to the horizontal cross-piece 12 can be adjusted at a preset spacing s.

In addition, because the base plate 15a of the fastening device 15 is joined to the vertical cross-piece 14 via the elongated aperture 15e of the base plate 15a, it can be continuously moved at least through a distance equal to the preset spacing s.

Accordingly, if the position of the vertical cross-pieces 14 is used for reference, then the position of the fastening device 15 can be adjusted in a continuous manner throughout a distance range equal to the preset spacing s, and, at the same time, if the position of the fastening device 15 is used for reference, then the position of the horizontal cross-piece 12 can be adjusted at a preset spacing s, and the position of the horizontal cross-piece 12 relative to the vertical cross-pieces 14 can be freely adjusted and set throughout the length of the horizontal cross-piece 12 by adjusting both of them together.

As noted above, in order to facilitate the adjustment of the position of the horizontal cross-piece 12 relative to the vertical cross-pieces 14, the length a of the elongated aperture 15e in the base plate 15a of the fastening device 15 may be made adequately longer than the distance b (a>b).

Because in such a case the position of the horizontal cross-piece 12 relative to the vertical cross-pieces 14 can be freely adjusted, the horizontal cross-piece 12 can be secured at arbitrary locations on the vertical cross-pieces 14.

Although the horizontal cross-piece 12 is produced by interconnecting multiple cross-piece members 12P and multiple through holes 12h are formed in the respective cross-piece members 12P at a preset spacing s, for any of the cross-piece members 12P, the position of the cross-piece member 12P relative to the vertical cross-pieces 14 can be freely adjusted and set throughout the length of the cross-piece member 12P and the cross-piece members 12P can be brought in abutment with each other on the vertical cross-pieces 14.

In the same manner as at the point of interconnection between the cross-piece members 11P, an interconnecting device 29 fits inside the U-shaped cross-sectional shape of the cross-piece members 12P at the point of interconnection between the cross-piece members 12P such that the oblong apertures 29d of the interconnecting device 29 overlap with the respective through holes 12h spaced apart at a preset spacing s so as to sandwich the point of interconnection between the cross-piece members 12P, multiple bolts 18a are passed through the oblong apertures 29d and through holes 12h, and respective nuts 18b are threadedly engaged with, and tightened on, these bolts 18a.

In addition, when the point of interconnection of the cross-piece members 12P is secured to the vertical cross-piece members 14, an interconnecting device 29 and a fastening device 15 are both disposed at this point of interconnection and the upright plates 12c of the cross-piece members 12P are sandwiched between the upright plate 29a of the interconnecting device 29 and the supporting plate 15c of the fastening device 15 such that the oblong apertures 29d of the interconnecting device 29, through holes 12h of the cross-piece members 12P, and screw holes 15f of the fastening device 15 are mutually superposed. The two bolts 18a are threadedly engaged with the screw holes 15f via the oblong apertures 29d and through holes 12h and tightened. In addition, another two bolts 18a are threadedly engaged with nuts via the oblong apertures 29d and through holes 12h and tightened. This improves the strength of the point of interconnection of the cross-piece members 12P.

On the other hand, the spacing between the horizontal cross-pieces 11, 12 is adjusted by adjusting the position of both of the horizontal cross-pieces 11, 12 in the X direction. The adjustment of this spacing is performed by placing the respective beam members 13 in multiple locations on the cross-pieces 11, 12 in a bridging manner.

As shown in FIG. 11a, a pair of through holes 13i are formed in the end section 13h of the beam member 13 and a pair of through holes 13j are formed in a region of the beam member 13 spaced a prescribed distance from the through holes 13i.

As shown in FIG. 2, the beam members 13 are placed on the horizontal cross-pieces 11, 12 in a bridging manner, with the beam members 13 bent downward. The horizontal cross-pieces 11, 12 are then moved in the Y direction on the vertical cross-pieces 14 such that the through holes 13i of the end section 13h of the beam member 13 overlap with the through holes 12i of the top plate 12a of the horizontal cross-piece 12 and, at the same time, the through holes 13j of the beam member 13 overlap with the through holes 11i of the top plate 11a of the horizontal cross-piece 11. This adjusts the spacing between the horizontal cross-pieces 11, 12. After this, two bolts 19a are passed through the through holes 13i of the end section 13h of the beam member 13 and the through holes 12i of the top plate 12a of the horizontal cross-piece 12, respective nuts are threadedly engaged with the bolts 19a and tightened. In the same manner, two bolts 19a are passed through the through holes 13j of the beam member 13 and the through holes 11i of the top plate 11a of the horizontal cross-piece 11, respective nuts are threadedly engaged with the bolts 19a and tightened, thereby setting the spacing between the horizontal cross-pieces 11, 12.

It should be noted that the beam member 13 may be mounted in a bridging manner at the point of interconnection between the cross-piece members 11P and at the point of interconnection between the cross-piece members 12P, but the through holes 11i, 12i used for mounting the beam member 13 are not occluded because the through holes 28e, 29e of the top plates 28c, 29c of the interconnecting devices 28, 29 overlap with the through holes 11i, 12i of the top plates 11a, 12a of the horizontal cross-pieces 11, 12 (see FIG. 14 and FIG. 15).

After adjust the position of the horizontal cross-pieces 11, 12 in the X direction and setting the spacing between the horizontal cross-pieces 11, 12 in the Y direction in this manner, the horizontal cross-pieces 11, 12 are secured to the vertical cross-pieces 14 using the fastening devices 15 as described above.

After that, solar cell modules 2 are placed on the top plates 11a, 12a of the horizontal cross-pieces 11, 12 in a bridging manner by arranging the solar cell modules 2 such that the centers of the solar cell modules 2 overlap with the beam members 13. As noted above, the beam members 13 are bent downward, as a result of which the inner frames (not shown) of the solar cell modules 2 do not have gaps in contact with the beam members 13 and the solar cell modules 2 can be reliably mounted onto the top plates 11a, 12a of the horizontal cross-pieces 11, 12. Although the solar cell modules 2 are inclined when placed on the top plates 11a, 12a of the horizontal cross-pieces 11, 12, the frame members 21 of the solar cell modules 2 abut the stoppers 13g of the beam members 13 on the tilted lower side thereof, and, as a result, the solar cell modules 2 are precisely positioned on the top plates 11a, 12a and, at the same time, the solar cell modules 2 are prevented from slipping off.

Furthermore, the solar cell modules 2 are secured to, and supported by, the horizontal cross-pieces 11, 12 with the help of the mounting fitting units 26 or 27. A support structure utilizing the mounting fitting units 26 or 27 is explained in detail below.

Thus, in the structure installation mount 10 of the present embodiment, two screw holes 15f are formed at a preset spacing sin the supporting plate 15c of the fastening device 15 and multiple through holes 11h, 12h are formed at a preset spacing sin the upright plates 11c, 12c of the horizontal cross-pieces 11, 12, as a result of which the location where the fastening device 15 is joined to the horizontal cross-piece 11,12 can be adjusted at a preset spacing s. In addition, the base plate 15a of the fastening device 15 is joined to the vertical cross-piece 14 via the elongated aperture 15e in the base plate 15a with a length of a (a≧b), as a result of which the base plate 15a of the fastening device 15 can be moved at least through a distance equal to the preset spacing s and the mounting position of the fastening device 15 can be adjusted in a continuous manner within this distance range. Accordingly, if the position of the vertical cross-pieces 14 is used for reference, then the position of the fastening device 15 can be adjusted in a continuous manner at least throughout a distance range equal to the preset spacing s, and at the same time, if the position of the fastening device 15 is used for reference, then the position of the horizontal cross-pieces 11, 12 can be adjusted at a preset spacing s and, therefore, the position of the horizontal cross-pieces 11, 12 relative to the vertical cross-pieces 14 can be freely adjusted and set throughout the length of the horizontal cross-pieces 11, 12.

For this reason, even though the position of the vertical cross-pieces 14 on the flat roof is uncertain, the horizontal cross-pieces 11, 12 can be secured at arbitrary locations on the vertical cross-pieces 14.

In addition, since the horizontal cross-pieces 11, 12 have a U-shaped cross-sectional shape and the fastening devices 15 have an L-shaped cross-sectional shape, inexpensive materials of superior strength, such as galvanized steel sheet and the like, can be used for the horizontal cross-pieces 11, 12 and fastening devices 15.

Furthermore, since the stopper 13g of the beam member 13 protrudes beyond the horizontal cross-piece 11, the end section on the tilted lower side of the solar cell module 2 also protrudes beyond the horizontal cross-piece 11. For this reason, even if rainwater flows towards the end section on the tilted lower side of the solar cell module 2 and drips off the end section, the rainwater does not fall on the horizontal cross-piece 11, which makes it possible to prevent corrosion of the horizontal cross-piece 11.

The mounting structure of the frame member 21 of the solar cell module 2 used for the horizontal cross-pieces 11, 12 of the structure installation mount 10 will be described next.

In FIG. 1 and FIG. 2, as noted above, the mounting fitting units 26 are intended for simultaneously securing the frame members 21 of two mutually adjacent solar cell modules 2 in the solar photovoltaic system 1. In addition, the mounting fitting units 27 are intended for securing the frame members 21 of the solar cell modules 2 located at the opposite side edges of the solar photovoltaic system 1. Accordingly, the construction of the mounting fitting units 26 and mounting fitting units 27 is somewhat different. For this reason, the respective mounting structures involving the mounting fitting units 26 and mounting fitting units 27 will be described separately.

The mounting fitting unit 26 used for simultaneously securing the frame members 21 of the two mutually adjacent solar cell modules 2 of the solar photovoltaic system 1 will be described first.

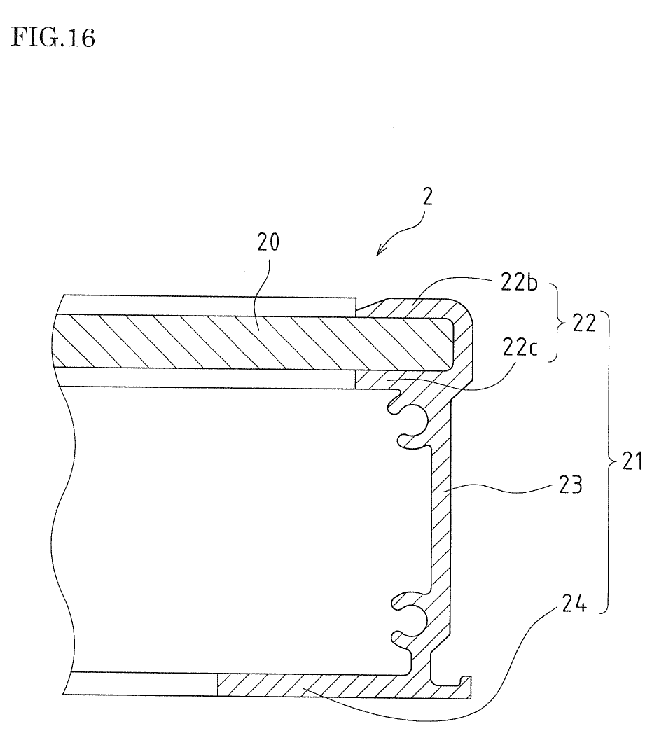

As shown in FIG. 16, the frame member 21 of a solar cell module 2 has a wall section 23, a holding section 22 above the wall section 23, and a bottom piece 24, which extends from inwardly in the horizontal direction the lower end of the wall section 23.

The holding sections 22 has a pair of holding pieces 22b, 22c, with the end section of the solar cell panel 20 sandwiched between these holding pieces 22b, 22c.

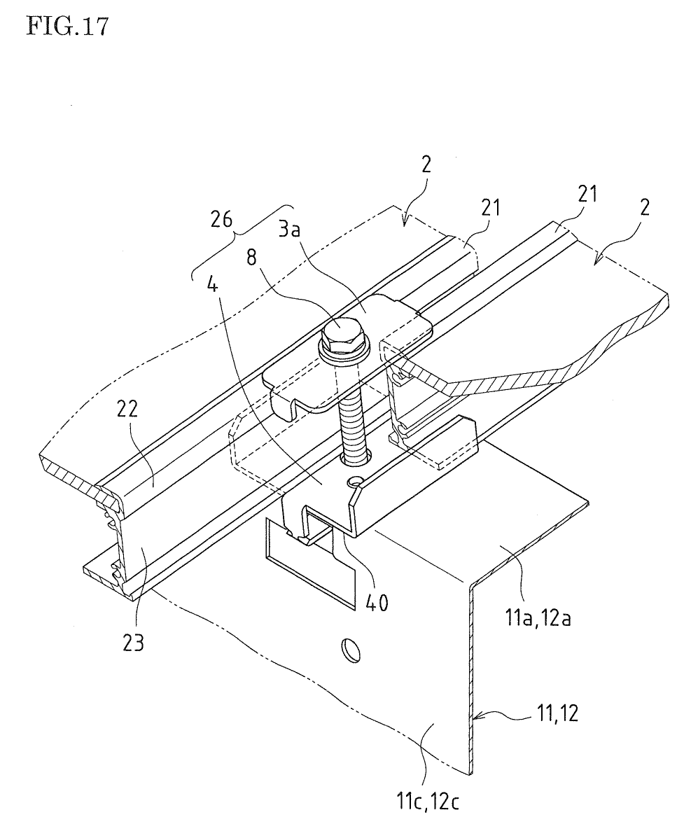

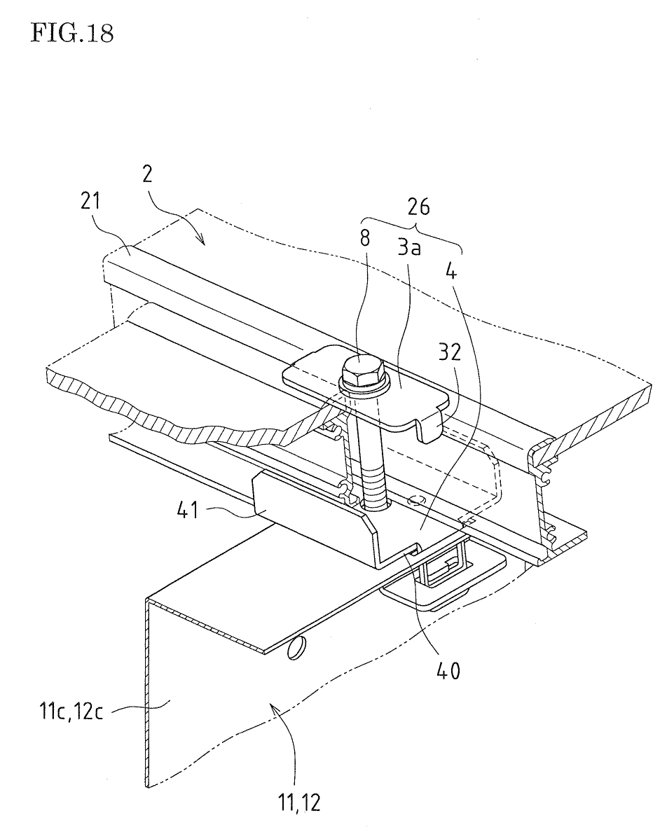

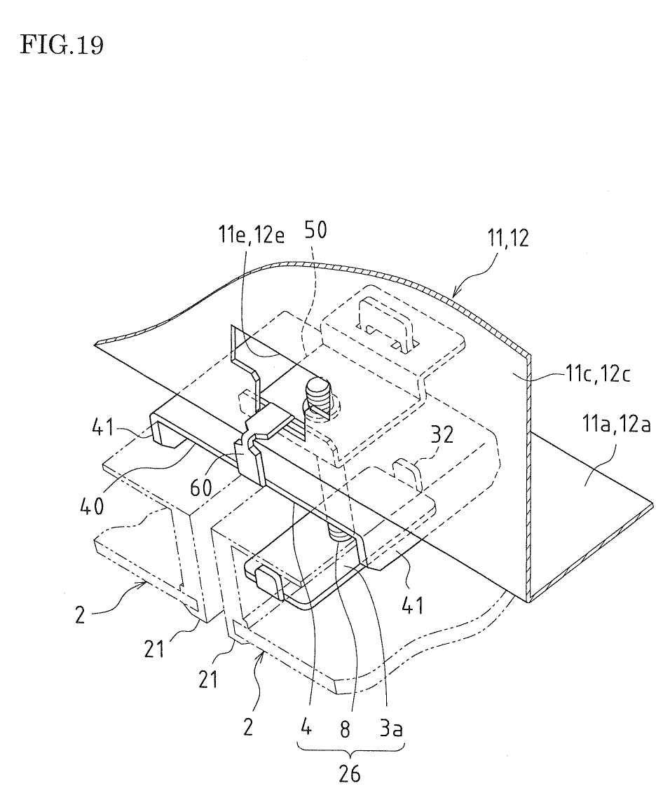

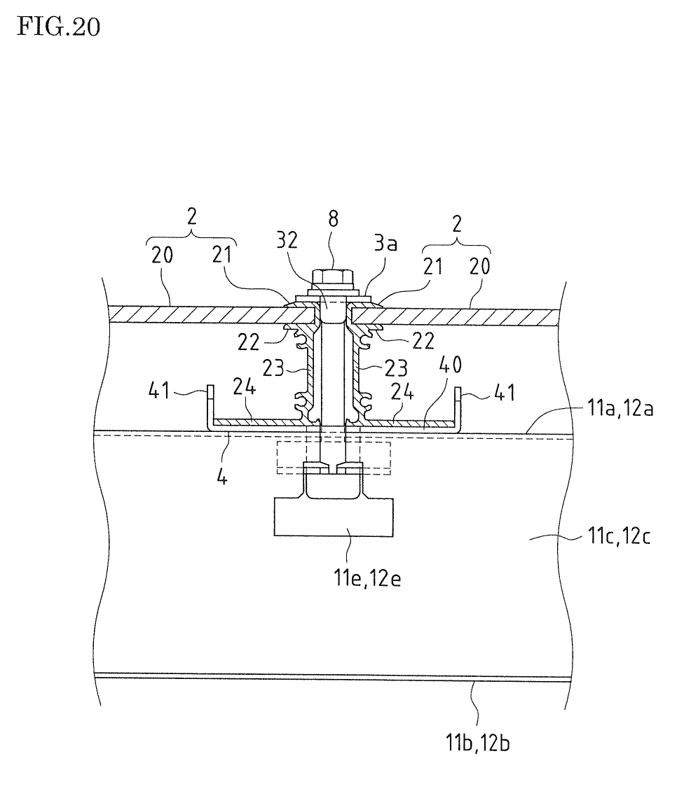

FIG. 17 and FIG. 18 are perspective views illustrating the end sections of mutually adjacent solar cell modules 2 secured using a mounting fitting unit 26 mounted to the horizontal cross-piece 11 (or 12), as seen from above. In addition, FIG. 19 is a perspective view illustrating the same state from below. In addition, FIG. 20 is cross-sectional view illustrating the same state.

As shown in FIGS. 17-20, the mounting fitting unit 26 includes a compression fitting 3a, a load-bearing fitting 4, and a bolt 8 that joins the fittings 3a and 4. The load-bearing fitting 4 is mounted to the horizontal cross-piece 11 (or 12) and receives the bottom side of the frame members 21 of the right- and left-hand solar cell modules 2. In addition, the compression fitting 3a is brought into abutment against the front side of the frame members 21 of the right- and left-hand solar cell modules 2. Furthermore, the bolt 8 passes through the compression fitting 3a all the way to the reverse side of the top plate 11a (or 12a) of the horizontal cross-piece 11 (or 12) and is threadedly engaged with the load-bearing fitting 4 on the reverse side. As a result, the frame members 21 of the right- and left-hand solar cell modules 2 are sandwiched between and supported by the fittings 3a, 4.

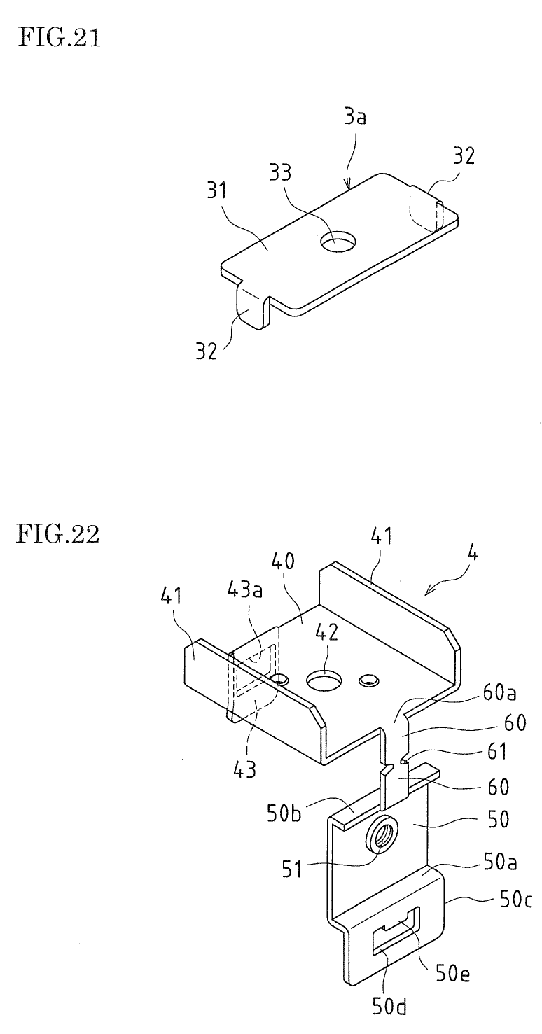

FIG. 21 is a perspective view illustrating the compression fitting 3a. As shown in FIG. 21, the compression fitting 3a has downwardly protruding protuberances 32 formed in the front and rear end sections of a plate-shaped push plate 31, as well as a through hole 33 formed in the central portion of the push plate 31.

The push plate 31 is used to apply pressure from above to the frame members 21 of the two solar cell modules 2 disposed in adjacent relationship on the top plate 11a (or 12a) of the horizontal cross-piece 11 (or 12). In addition, the through hole 33 in the push plate 31 is used to insert the bolt 8. The protuberances 32 of the compression fitting 3a are inserted between the right- and left-hand solar cell modules 2, thereby setting the spacing, at which the right- and left-hand solar cell modules 2 are disposed.

FIG. 22 is a perspective view illustrating the load-bearing fitting 4. As shown in FIG. 22, the load-bearing fitting 4 has a load-bearing plate 40, a back plate 50, and a joint section 60 that links the back plate 50 to the load-bearing plate 40. A waist section 61 is provided on midway through the joint section 60 in order to facilitate bending.

In the back plate 50, there is formed a rear wall 50b, which is bent at right angles from the rearward edge, and a front wall 50a, which is bent at right angles from the forward edge. Furthermore, there is formed an engagement piece 50c, which is bent at right angles from the edge of the front wall 50a, and a slot 50d is formed in this engagement piece 50c.

Upwardly bent claw pieces 41, 41 are formed at two edges of the load-bearing plate 40. In addition, a downwardly bent positioning piece 43, is formed at the rearward edge of the load-bearing plate 40 and an engagement groove 43a is formed in this positioning piece 43.

In addition, a through hole 42 is formed though the thickness of the central portion of the load-bearing plate 40, and a screw hole 51 is formed in the back plate 50. The bolt 8 is passed through the through hole 42 in the load-bearing plate 40, after which the bolt 8 is threadedly engaged with the screw hole 51 in the back plate 50.

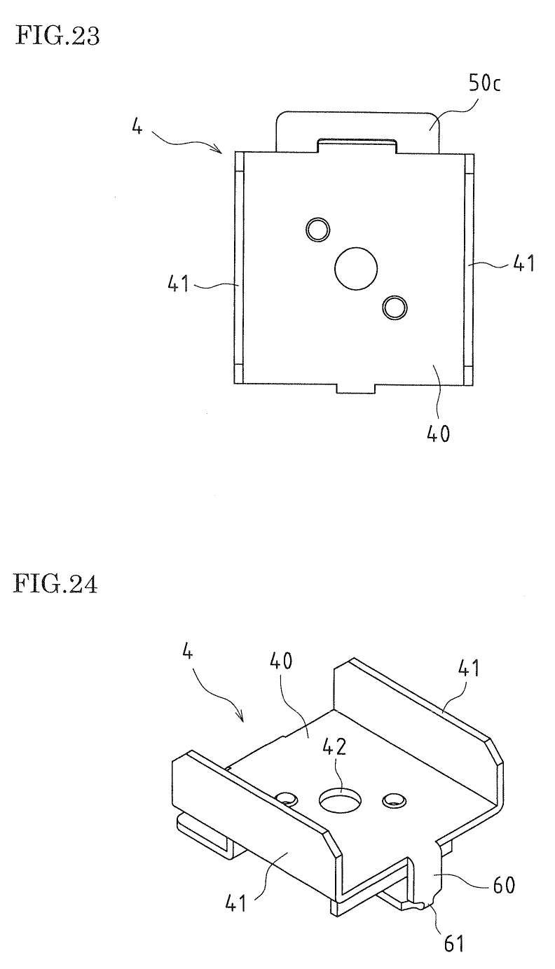

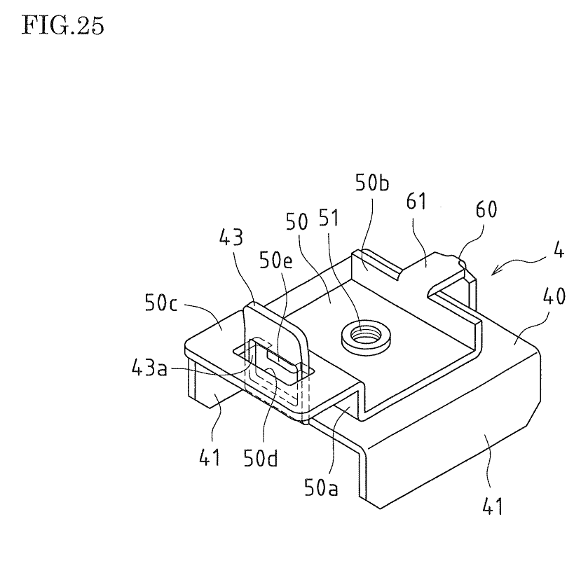

As shown in FIG. 23-FIG. 25, the joint section 60 of the load-bearing fitting 4 is bent in the waist section 61, the load-bearing plate 40 and the back plate 50 are disposed in a face-to-face relationship with a gap therebetween, the positioning piece 43 of the load-bearing plate 40 is fitted into the slot 50d of the engagement piece 50c of the back plate 50, and a protruding portion 50e of the engagement piece 50c is fitted into the slot 43a of the positioning piece 43, thereby mutually engaging the load-bearing plate 40 and the back plate 50.

On the other hand, as shown in FIG. 5(a)-(c) and FIG. 6(a)-(c), a T-shaped hole lie (or 12e) used for mounting the mounting fitting unit 26 (or 27) is formed in the upright plate 11c (or 12c) of the horizontal cross-piece 11 (or 12), and, in addition, an oblong aperture 11g (or 12g) and a positioning slit 11f (or 12f) used for mounting the mounting fitting unit 26 (or 27) are formed in the top plate 11a (12a).

The oblong aperture 11g (or 12g) in the top plate 11a (12a), which is used for inserting the bolt 8, is formed in the shape of an elongated slot to permit fine adjustment of the position of insertion of this bolt 8. In addition, the positioning slit 11f (or 12f), which is used for inserting the positioning piece 43 of the load-bearing fitting 4, is formed in the shape of an elongated slot to permit fine adjustment of the position of insertion of the positioning piece 43 of this load-bearing fitting 4.

In order to mount the load-bearing fitting 4 to such a horizontal cross-piece 11 (or 12), first of all, the back plate 50 of the load-bearing fitting 4 prior to bending, as shown in FIG. 22, is passed through the T-shaped hole 11e (or 12e) of the upright plate 11c (or 12c) of the horizontal cross-piece 11 (or 12) and inserted up to the joint section 60 of the load-bearing fitting 4 into the T-shaped hole 11e (or 12e).

Subsequently, the waist section 61 of the joint section 60 of the load-bearing fitting 4 is bent 90 degrees to arrange the back plate 50 and load-bearing plate 40 in a face-to-face relationship, with the top plate 11a (or 12a) disposed therebetween, such that the top plate 11a (or 12a) is sandwiched between the back plate 50 and load-bearing plate 40 and the load-bearing fitting 4 is mounted to the top plate 11a (or 12a). At such time, the positioning piece 43 of the load-bearing fitting 4 is inserted into the positioning slit 11f (or 12f) of the top plate 11a (or 12a), thereby positioning the load-bearing fitting 4. In addition, the positioning piece 43 of the load-bearing plate 40 is fitted into the slot 50d of the engagement piece 50c of the back plate 50 and the protruding section 50e of the engagement piece 50c is fitted into the slot 43a of the positioning piece 43, thereby mutually engaging the load-bearing plate 40 and the back plate 50.

As shown in FIG. 20, with the load-bearing fitting 4 mounted to the top plate 11a (or 12a) in this manner, the bottom piece 24 of the frame member 21 of the left-hand solar cell module 2 is inserted and arranged in the space between the central area of the load-bearing plate 40 of the load-bearing fitting 4 and the left-hand claw piece 41. At the same time, the bottom piece 24 of the frame member 21 of the right-hand solar cell module 2 is inserted and arranged in the space between the central area of the load-bearing plate 40 to the right-hand claw piece 41. The compression fitting 3a is placed on the holding section 22 of the frame member 21 of the solar cell modules 2, the protuberances 32 of the compression fitting 3a are inserted between the right- and left-hand solar cell modules 2, the bolt 8 is inserted into the through hole 33 of the compression fitting 3a and the through hole 42 of the load-bearing plate 40 such that the bolt 8 passes through the oblong aperture 11g (or 12g) of the top plate 11a (or 12a) and is threadedly engaged with, and tightened in, the screw hole 51 of the back plate 50. As a result, the frame members 21 of the right- and left-hand solar cell modules 2 are sandwiched between, secured, and supported by the load-bearing fitting 4 and compression fitting 3a.

The mounting fitting unit 27 used for securing the frame members 21 of the solar cell modules 2 located at the opposite side edges of the solar photovoltaic system 1 will be described next.

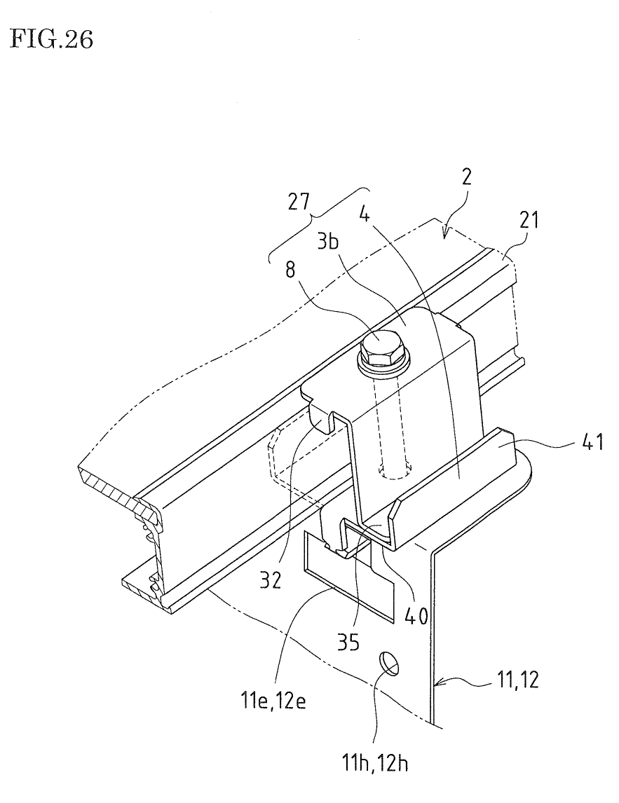

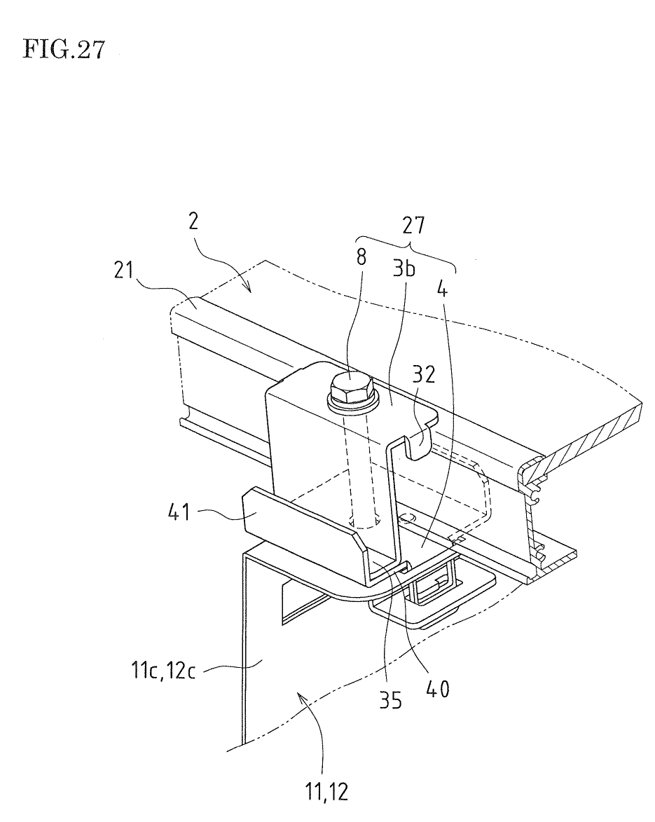

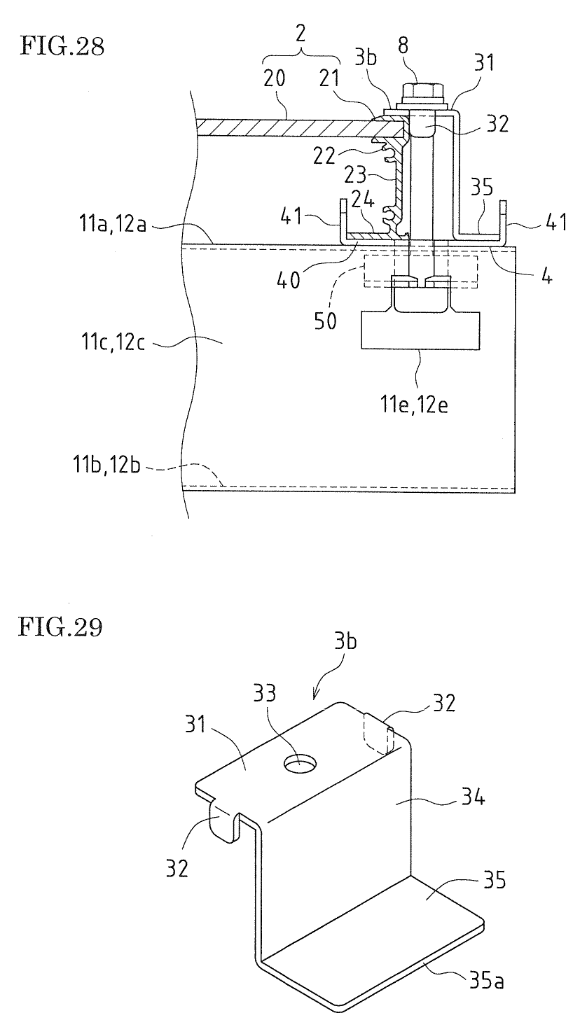

FIG. 26 and FIG. 27 are perspective views illustrating the end sections of the right- and left-hand solar cell modules 2 secured using mounting fitting units 27 mounted to the horizontal cross-piece 11 (or 12), as seen from above. In addition, FIG. 28 is cross-sectional view illustrating the same state.

As shown in FIG. 26-FIG. 28, the mounting fitting unit 27 includes a compression fitting 3b, a load-bearing fitting 4, and a bolt 8 joining the fittings 3b and 4. The load-bearing fitting 4 has the same configuration as the load-bearing fitting 4 of the mounting fitting units 26, and the structure or procedure used for mounting it to the horizontal cross-piece 11 (or 12) is the same. In addition, the compression fitting 3b is brought into abutment against the front side of the frame member 21 of a solar cell module 2. Furthermore, a bolt 8 passes through the compression fitting 3b all the way to the reverse side of the top plate 11a (or 12a) of the horizontal cross-piece 11 (or 12) and is threadedly engaged with the load-bearing fitting 4 on the reverse side. As a result, the frame member 21 of the solar cell module 2 is sandwiched between and supported by the fittings 3b, 4.

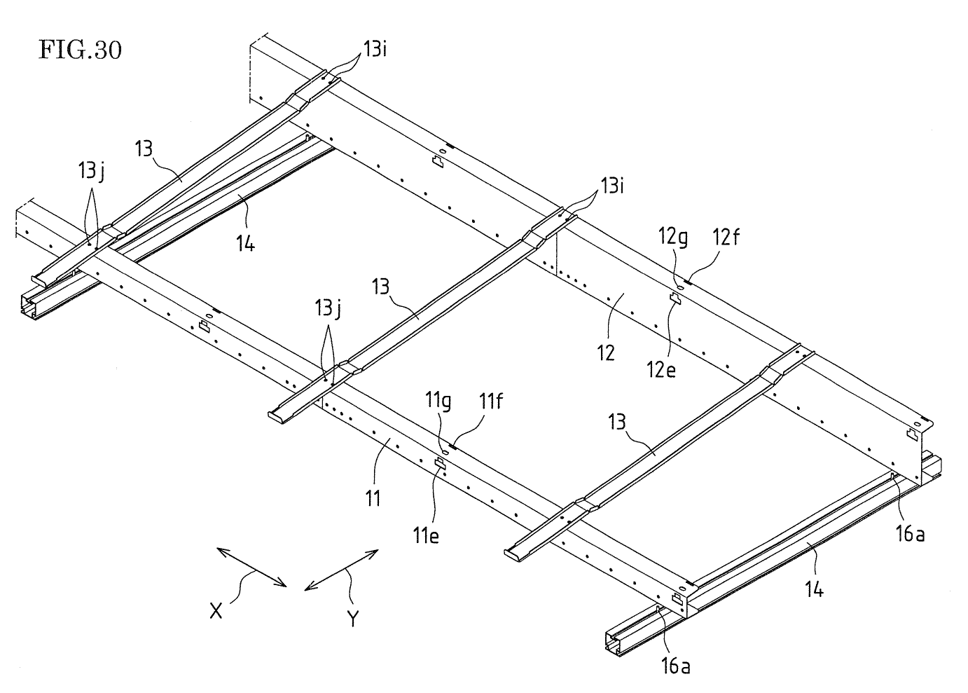

FIG. 29 is a perspective view illustrating the compression fitting 3b. As shown in FIG. 29, the compression fitting 3a has downwardly protruding protuberances 32 formed in the front and rear end sections of a plate-shaped push plate 31, as well as a through hole 33 formed in the central portion of the push plate 31. A raised wall 34 is formed by bending at right angles at one edge of the push plate 31 and a bottom piece 35 is formed by bending laterally from the lower edge of the raised wall 34.

As shown in FIG. 28, the bottom piece 24 of the frame member 21 of the left-hand or right-hand solar cell module 2 is inserted and arranged in the space between the central area of the load-bearing plate 40 of the load-bearing fitting 4 and the inner claw piece 41. In addition, the bottom piece 35 of the compression fitting 3b is arranged in the space between the central area of the load-bearing plate 40 and the outer claw piece 41. The push plate 31 of the compression fitting 3b is placed on the holding section 22 of the frame member 21 of the solar cell module 2 and the protuberances 32 of the compression fitting 3b are pressed against the holding section 22 of the solar cell module 2, thereby positioning the solar cell module 2. After inserting the bolt 8 into the through hole 33 of the compression fitting 3b and the through hole 42 of the load-bearing plate 40 of load-bearing fitting 4, the bolt 8 is passed through the oblong aperture 13 of the top plate 12 and threadedly engaged with the screw hole 51 of the back plate 50, after which the bolt 8 is tightened. As a result, the frame member 21 of the solar cell module 2 is sandwiched between, secured, and supported by the load-bearing fitting 4 and compression fitting 3b.

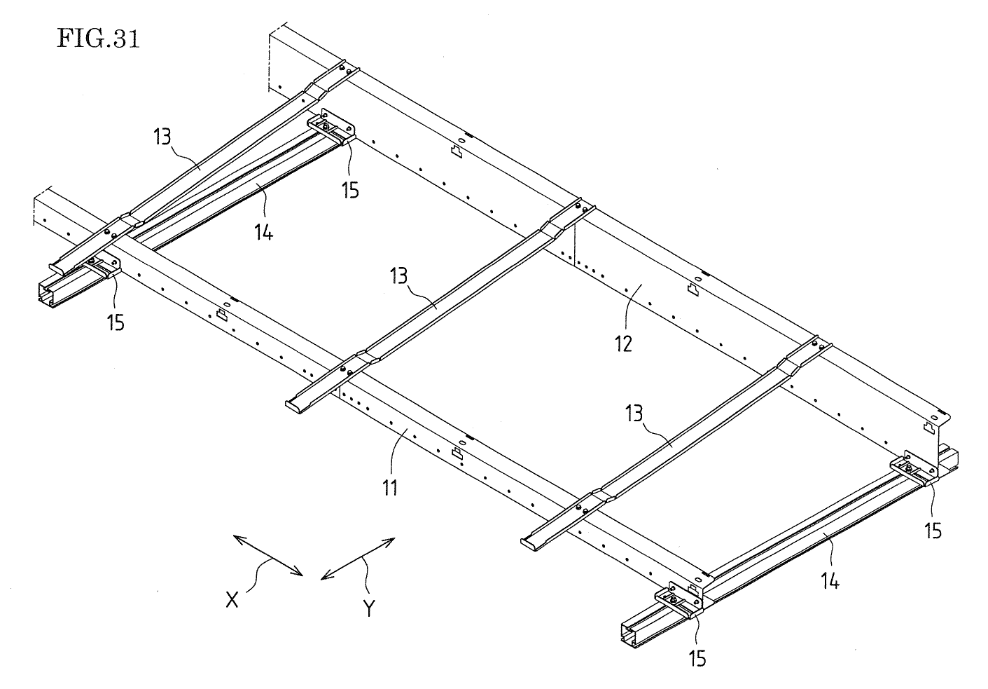

A procedure for installing the solar photovoltaic system 1 of FIG. 1 will be described next. The description will be given with reference to FIG. 30-FIG. 32.

First of all, as shown in FIG. 30, the longitudinal direction of multiple vertical cross-pieces 14 is oriented in the Y direction and these vertical cross-pieces 14 are disposed parallel to each other and secured to a foundation surface, such as a flat roof and the like. The spacing and positions of these vertical cross-pieces 14 are undetermined.

With the heads of the two bolts 16a inserted into the mating groove 14b of each vertical cross-piece 14 and the shank sections of the bolts 16a protruding from the narrow width slit of the mating groove 14b, the bolts 16a are disposed at a distance corresponding to the gap between the horizontal cross-pieces 11, 12.

The horizontal cross-pieces 11, 12 are placed on the vertical cross-pieces 14 facing in the direction (X direction), in which the horizontal cross-pieces 11, 12 are at right angles to the vertical cross-pieces 14, and the horizontal cross-pieces 11, 12 are positioned by moving them in the X direction.

In addition, the adjustment of the spacing between the horizontal cross-pieces 11, 12 is performed by placing the respective beam members 13 in multiple locations on the horizontal cross-pieces 11, 12 in a bridging manner.

As shown in FIG. 31, the respective shank sections of the bolts 16a are passed through the elongated apertures 15e in the base plates 15a of the fastening devices 15 and the base plates 15a of the fastening devices 15 are placed on the upper surfaces 14a of the vertical cross-pieces 14 and, in each fastening device 15, the supporting plate 15c of the fastening device 15 is brought into abutment against the upright plate 11c (or 12c) of the horizontal cross-piece 11 (or 12), the screw holes 15f of the supporting plate 15c of the fastening device 15 are made to overlap with the through holes 11h (or 12h) of the horizontal cross-piece 11 (or 12), and the upright plate 11c (or 12c) of the horizontal cross-piece 11 (or 12) is joined to the supporting plate 15c of the fastening device 15 with bolts and nuts. Furthermore, in each fastening device 15, the reinforcement fitting 25 is superimposed on the base plate 15a of the fastening device 15 and a nut 16b is threadedly engaged with, and tightened on, the shank section of the bolt 16a, thereby joining the fastening device 15 to the vertical cross-piece 14.

As a result, the horizontal cross-pieces 11, 12 are disposed and secured to the vertical cross-pieces 14 in parallel to each other at a predetermined spacing and the respective top plates 11a, 12a are positioned in substantially the same inclined plane.

In addition, the back plate 50 of the load-bearing fitting 4 is passed through the T-shaped hole lie (or 12e) in the horizontal cross-piece 11 (or 12) and inserted into the T-shaped hole lie (or 12e) up to the joint section 60 of the load-bearing fitting 4. The positioning piece 43 of the load-bearing fitting 4 is inserted into the positioning slit 11f (or 12f) of the top plate 11a (or 12a), thereby positioning the load-bearing fitting 4. The waist section 61 of the joint section 60 of the load-bearing fitting 4 is then bent 90 degrees to arrange the back plate 50 and load-bearing plate 40 in a face-to-face relationship, with the top plate 11a (or 12a) disposed therebetween, such that the load-bearing fitting 4 is mounted to the top plate 11a (or 12a).

In each solar cell module 2, this load-bearing fitting 4 is mounted in the respective locations of the horizontal cross-pieces 11, 12 so as to secure it in 4 locations on two sides of the frame member 21 of the solar cell module 2.

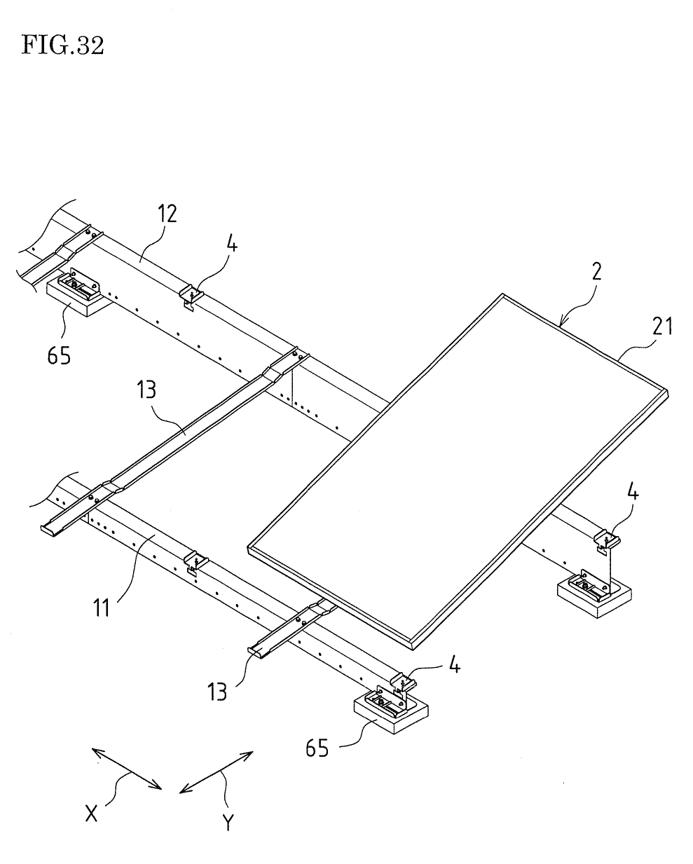

Next, as shown in FIG. 32, multiple solar cell modules 2 are arranged on the horizontal cross-pieces 11, 12 and, in each solar cell module 2, four locations on two sides of the frame member 21 of the solar cell module 2 are placed on four load-bearing fittings 4 on the horizontal cross-pieces 11, 12. The end sections on the tilted lower side of the solar cell modules 2 are brought into abutment against the stoppers 13g of the beam members 13, thereby positioning the solar cell modules 2. As a result, the solar cell modules 2 are supported at an angle parallel to the top plates 11a, 12a of the horizontal cross-pieces 11, 12.

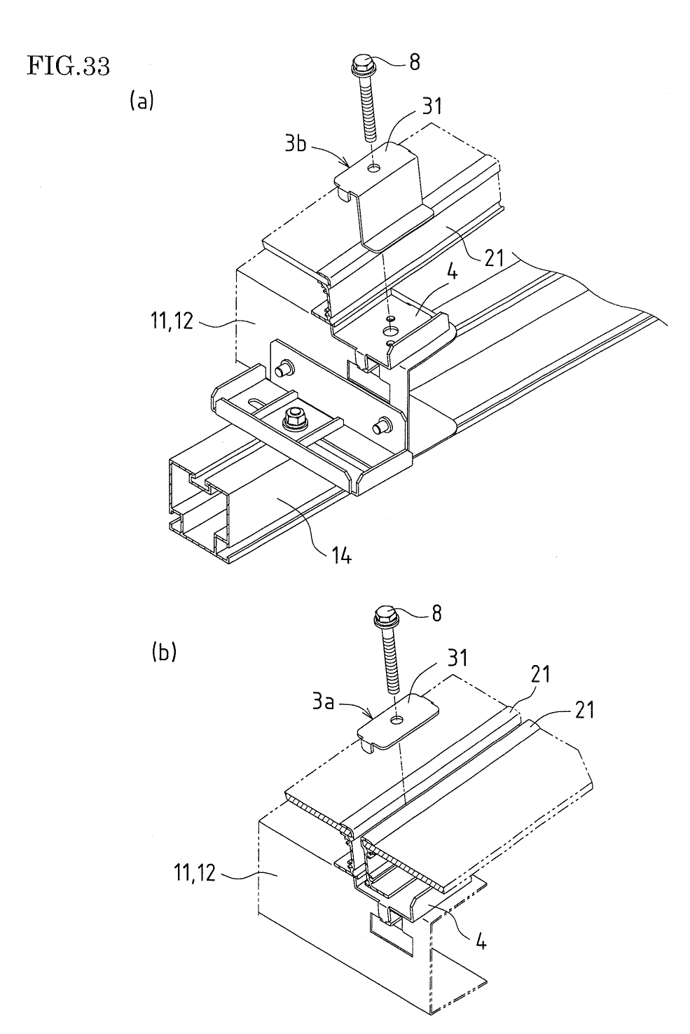

Then, as shown in FIG. 33(a) with respect to the frame members 21 of the solar cell modules 2 located at the opposite side edges of the solar photovoltaic system 1, the push plate 31 of the compression fitting 3b is placed on the frame member 21 of a solar cell module 2 and the bolt 8 is passed through the compression fitting 3b all the way to the reverse face of the top plate 11a (or 12a) of the horizontal cross-piece 11 (or 12) and then threadedly engaged and fastened to the back plate 50 of the load-bearing fitting 4 such that the frame member 21 of the solar cell module 2 is sandwiched, secured, and supported between the load-bearing fitting 4 and compression fitting 3b.

In addition, as shown in FIG. 33(b) with respect to the frame members 21 of two mutually adjacent solar cell modules 2, the push plate 31 of the compression fitting 3a is placed on the frame member 21 of a solar cell module 2 and the bolt 8 is passed through the compression fitting 3a all the way to the reverse face of the top plate 11a (or 12a) of the horizontal cross-piece 11 (or 12) and then threadedly engaged and fastened to the back plate 50 of the load-bearing fitting 4 such that the frame members 21 of the right- and left-hand solar cell modules 2 are sandwiched, secured, and supported between the load-bearing fitting 4 and compression fitting 3a.

A solar photovoltaic system 1, such as the one illustrated in FIG. 1, is assembled as a result.

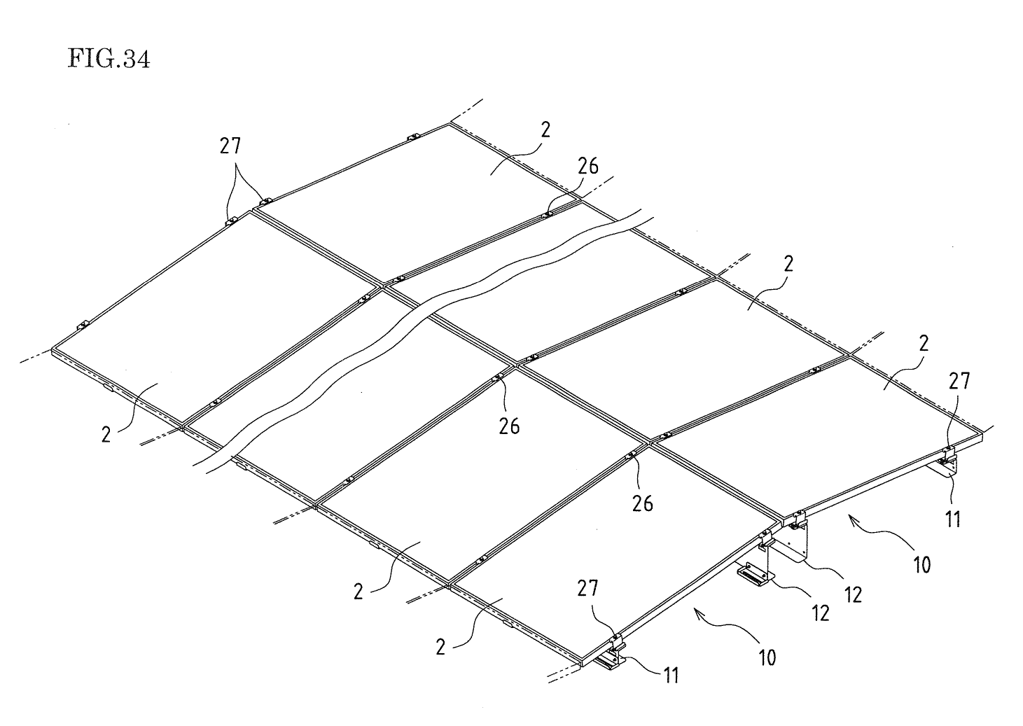

It should be noted that the present invention is not limited to the above-described embodiment and can be modified in many ways. For example, as shown in FIG. 34, there may be provided multiple columns of solar cell modules 2 and the solar cell modules 2 in each column may be arranged in a ridge-like configuration, with the tilt of the solar cell modules 2 in each column being opposite to that of the adjacent column. To produce this ridge-like arrangement, the higher horizontal cross-pieces 12 are disposed in 2 columns next to each other, the respective lower horizontal cross-pieces 11 are arranged on the outside of these 2 columns, and multiple solar cell modules 2 are mounted to the horizontal cross-pieces 11, 12.

Due to such an arrangement of the solar cell modules 2, even when there are multiple closely juxtaposed solar cell modules 2, the solar cell modules 2 are never in the shadow of other solar cell modules 2, which makes it possible to increase power generation efficiency.

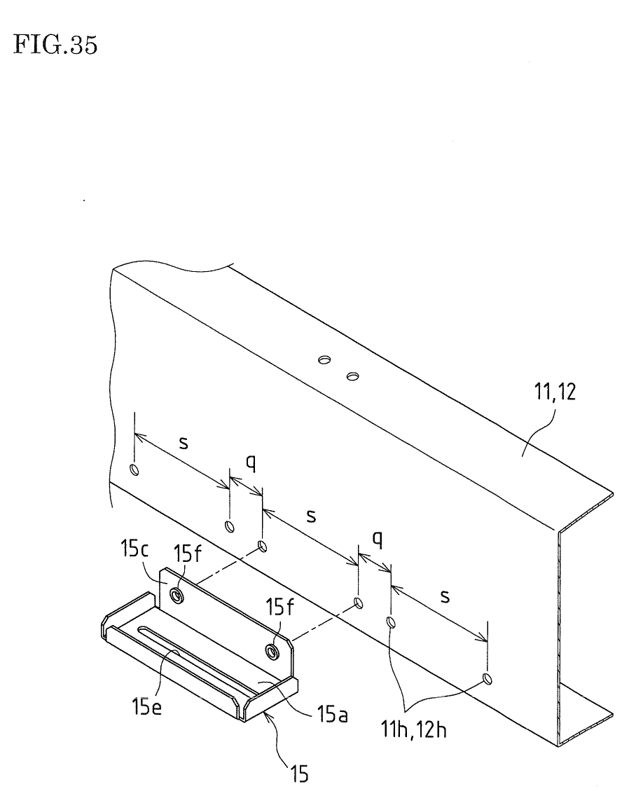

In addition, through holes 11h, 12h may be formed in the horizontal cross-piece 11 or 12 at the spacing illustrated in FIG. 35. Here, when two through holes 11h or 12h arranged at the preset spacing s and overlapping with the screw holes 15f of the supporting plate 15c of the fastening device 15 are viewed as a single group, multiple groups of through holes 11h or 12h are formed in the longitudinal direction of the horizontal cross-piece 11 or 12. Although the two through holes 11h or 12h are spaced at a preset spacing s within any of the groups, the spacing q between adjacent groups of through holes 11h is narrow and smaller than the preset spacing s. In this case, the screw holes 15f in the supporting plate 15c of the fastening device 15 overlap with one of the groups of through holes 11h or 12h in the horizontal cross-piece 11 or 12, thereby enabling the supporting plate 15c of the fastening device 15 to be joined to the horizontal cross-piece 11 or 12. In addition, if the length a of the elongated aperture 15e in the base plate 15a of the fastening device 15 is made sufficiently larger than the distance b measured in the screw holes 15f formed in the supporting plate 15 between the perimeter edge portions of the screw holes 15f that are at their greatest distance apart (a=b+q), the position of the horizontal cross-piece 11 or 12 relative to the vertical cross-pieces 14 can be freely adjusted and set throughout the length of the horizontal cross-piece 11 or 12.

In addition, although the structure installation mount of the present embodiment supports solar cell modules, instead of that, it may support reflector panels used for heliothermal power generation. This makes it possible to build a heliothermal power generation system.

### INDUSTRIAL APPLICABILITY

The structure installation mount of the present invention makes it possible to freely adjust and set the position of the cross-pieces relative to any location on a foundation within a wide range. Moreover, the support device for structure installation used in this structure installation mount does not have to use constructions involving cross-pieces and fastening devices of a complicated shape, which enables the use of inexpensive materials of superior strength such as steel and the like. In view of the above, a solar photovoltaic system built by mounting solar cell modules to the structure installation mount of the present invention can reflect the advantages of the structure installation mount and support device for structure installation of the present invention, and would be useful.

### DESCRIPTION OF REFERENCE NUMERALS

1 Solar photovoltaic system

2 Solar cell module

3a, 3b Compression fittings

4 Load-bearing fitting

10 Structure installation mount

11, 12 Horizontal cross-pieces (cross-pieces)

13 Beam member

14 Vertical cross-pieces (foundation cross-pieces)

15 Fastening device

15a Base plate (base section)

15c Supporting plate (supporting section)

28, 29 Interconnecting plates

20 Solar cell panel

21 Frame member

26, 27 Mounting fitting units

1. A structure installation mount including cross-pieces for mounting a structure and fastening devices that are used to secure these cross-pieces to a foundation, wherein
the fastening devices have a supporting section having formed therein at least two through holes which, upon mounting to the cross-pieces, are spaced apart lengthwise of the cross-pieces, and a base section having formed therein an elongated aperture that is equal to or longer than a distance between both outer sides of the through holes;
when the through holes formed in the supporting section of the fastening device and the respective through holes overlapping with these through holes are viewed as a single group, a plurality of groups of through holes are formed in the cross-pieces in a longitudinal direction of the cross-pieces;
the supporting section of the fastening device and the, cross-pieces are joined via mutually overlapping through holes in the supporting section of the fastening device and through holes in the cross-pieces; and
the base section of the fastening device is joined to the foundation through the elongated aperture in the fastening device.

2. The structure installation mount according to claim 1, wherein
the cross-pieces have an upright plate that is set upright on the foundation, and
a plurality of groups of through holes are formed in the upright plate in the longitudinal direction of the cross-pieces.

3. The structure installation mount according to claim 1, wherein
the cross-pieces are formed by interconnecting a plurality of cross-piece members, and
through holes respectively overlapping with the through holes in the supporting section of the fastening device are formed in two adjacent cross-piece members at a point of their interconnection such that the through holes sandwich the point of interconnection.

4. The structure installation mount according to claim 3, comprising an interconnecting device having formed therein through holes respectively overlapping with the through holes in the supporting section of the fastening device,
wherein the two cross-piece members are joined to the interconnecting device via mutually overlapping through holes in the cross-piece members and through holes in the interconnecting devices; and
the two cross-piece members are interconnected via the interconnecting device.

5. The structure installation mount according to claim 4, wherein
the point of interconnection between the two cross-piece members is sandwiched between the supporting section of the fastening device and the interconnecting device;
the two cross-piece members, the supporting section of the fastening device, and the interconnecting device are joined together via mutually overlapping through holes in the cross-piece members, through holes in the supporting section of the fastening device, and through holes in the interconnecting device; and
the two cross-piece members are interconnected via the fastening device and the interconnecting device.

6. The structure installation mount according to claim 1, wherein
the cross-pieces have a bottom plate, an upright plate bent from one edge of this bottom plate, and a top plate produced by bending from the top edge of the upright plate;
the two cross-pieces are disposed parallel to each other; the upright plates of the cross-pieces are secured to the foundation using the fastening devices; and
a structure is mounted onto the top plates of the cross-pieces in a bridging manner.

7. The structure installation mount according to claim 6, wherein
the heights of the cross-pieces secured to the foundation are different, the top plates of the cross-pieces are in substantially the same inclined plane, and the structure is mounted onto the top plates of the cross-piece members at an angle.

8. The structure installation mount according to claim 7, comprising a beam member secured between the cross-pieces in a bridging manner, and a stopper located at one end of the beam member is disposed on the inclined lower side of the structure placed on the top plates of the cross-pieces and is provided so as to receive one edge of the structure.

9. The structure installation mount according to claim 1, wherein
the foundation is formed from foundation cross-pieces extending in a direction perpendicular to the above-mentioned cross-pieces and the base section of the fastening device is joined to the foundation cross-pieces via the elongated aperture in the base section.

10. A support device for structure installation including cross-pieces and fastening devices, wherein
the fastening devices have a supporting section having formed therein at least two through holes which, upon mounting to a cross-piece, are spaced apart lengthwise of the cross-piece, and a base section having formed therein an elongated aperture that is equal to or longer than a distance between both outer sides of the through holes and,
when the through holes formed in the supporting sections of the fastening device and the respective through holes overlapping with these through holes are viewed as a single group, a plurality of groups of through holes are formed in the cross-pieces in a longitudinal direction of the cross-pieces.

11. A solar photovoltaic system obtained by mounting a solar cell module, i.e. structure, to a structure installation mount according to claim 1.
